(19) United States
(12) Patent Application Publication
(10) Pub. No.: US 2024/0074283 A1
(43) Pub. Date: Feb. 29, 2024

(54) LIGHT EMITTING AND RECEIVING DEVICE AND ELECTRONIC DEVICE

(71) Applicants: SONY GROUP CORPORATION, TOKYO (JP); SONY SEMICONDUCTOR SOLUTIONS CORPORATION, KANAGAWA (JP)

(72) Inventors: TAKEO TSUKAMOTO, TOKYO (JP); NAOYA KASAHARA, KANAGAWA (JP)

(21) Appl. No.: 18/261,178

(22) PCT Filed: Jan. 13, 2022
(86) PCT No.: PCT/JP2022/000948

§ 371 Date: Jul. 12, 2023

(30) Foreign Application Priority Data
Jan. 22, 2021 (JP) 2021-008993

(51) Int. Cl. H10K 59/65; H01L 27/146; H10K 59/35; H10K 59/38

(52) U.S. Cl. CPC H10K 59/65; H01L 27/14621; H01L 27/14645; H01L 27/14649; H10K 59/351; H10K 59/38

(57) ABSTRACT

Provided is a light emitting and receiving device capable of causing light to exit to outside and receiving light from outside.

The light emitting and receiving device includes a plurality of light emitting elements and a plurality of light receiving elements. The plurality of light emitting elements is two-dimensionally arranged separately. The plurality of light receiving elements is two-dimensionally arranged at a height different from a height of the plurality of light emitting elements, and each light receiving element faces an inter-element separation portion between adjacent light emitting elements.

### TECHNICAL FIELD

The present disclosure relates to a light emitting and receiving device and an electronic device including the light emitting and receiving device.

### BACKGROUND ART

In recent years, a light emitting and receiving device including a plurality of light emitting elements and a plurality of light receiving elements has been studied. For example, Patent Documents 1 and 2 propose a technique of detecting a degradation degree of a light emitting element and correcting luminance, by arranging a light receiving element to face the light emitting element and receiving exit light of the light emitting element with the light receiving element.

### CITATION LIST

### Patent Document

Patent Document 1: Japanese Patent Application Laid-Open No. 2011-071277
Patent Document 2: Japanese Patent Application Laid-Open No. 2003-167550

### SUMMARY OF THE INVENTION

### Problems to be Solved by the Invention

In recent years, a light emitting and receiving device capable of causing light to exit to outside and receiving light from outside has been desired. In Patent Documents 1 and 2, a configuration in which the light receiving element receives exit light of the light emitting element has been studied, but a configuration in which the light receiving element receives external light has not been studied.

An object of the present disclosure is to provide a light emitting and receiving device capable of causing light to exit to outside and receiving light from outside, and an electronic device including the light emitting and receiving device.

### Solutions to Problems

In order to solve the problem described above, a first disclosure is a light emitting and receiving device including:
a plurality of light emitting elements; and
a plurality of light receiving elements, in which
the plurality of light emitting elements is two-dimensionally arranged separately, and
the plurality of light receiving elements is two-dimensionally arranged at a height different from a height of the plurality of light emitting elements, and each of the light receiving elements faces an inter-element separation portion between the light emitting elements that are adjacent.

A second disclosure is an electronic device including the light emitting and receiving device of the first disclosure.

### BRIEF DESCRIPTION OF DRAWINGS

FIG. 1 is a plan view illustrating an example of a configuration of a light emitting and receiving device according to a first embodiment of the present disclosure.

FIG. 2 is a cross-sectional view taken along line II-II of FIG. 1.

FIG. 3 is a schematic diagram illustrating an example of a circuit configuration of the light emitting and receiving device according to the first embodiment of the present disclosure.

FIG. 4 is a block diagram illustrating an example of a configuration of a light emission and reception processing device.

FIG. 5 is a time chart for explaining an example of an operation of the light emission and reception processing device.

FIG. 6 is a cross-sectional view for explaining a first operation mode.

FIG. 7 is a cross-sectional view for explaining a second operation mode.

FIG. 8 is a cross-sectional view illustrating an example of a configuration of a light emitting and receiving device according to a second embodiment of the present disclosure.

FIG. 9 is a cross-sectional view illustrating an example of a configuration of a light emitting and receiving device according to Modification 1.

FIG. 10 is a cross-sectional view illustrating an example of a configuration of a light emitting and receiving device according to Modification 2.

FIG. 11 is a cross-sectional view illustrating an example of a configuration of a light emitting and receiving device according to Modification 3.

FIG. 12 is a cross-sectional view illustrating an example of a configuration of a light emitting and receiving device according to Modification 4.

FIG. 13 is a cross-sectional view illustrating an example of a configuration of a light emitting and receiving device according to Modification 5.

FIG. 14 is a plan view illustrating an example of a configuration of a light emitting and receiving device according to Modification 6.

FIG. 15 is a plan view illustrating an example of a configuration of a light emitting and receiving device according to Modification 7.

FIG. 16 is a plan view illustrating an example of a configuration of the light emitting and receiving device according to Modification 7.

FIG. 17 is a plan view illustrating an example of a configuration of the light emitting and receiving device according to Modification 7.

FIG. 18 is a perspective view illustrating an example of an external appearance of a head mounted display.

FIG. 19 is a perspective view illustrating an example of an external appearance of a display device.

### MODE FOR CARRYING OUT THE INVENTION

Embodiments of the present disclosure will be described in the following order. Note that, in all the drawings of the following embodiments, the same or corresponding parts are denoted by the same reference numerals.
1 First embodiment (example of light emitting and receiving device)
2 Second embodiment (example of light emitting and receiving device)
3 Modification (modification of light emitting and receiving device)
4 Application example (example of electronic device)

### 1 First Embodiment

[Configuration of Light Emitting and Receiving Device]

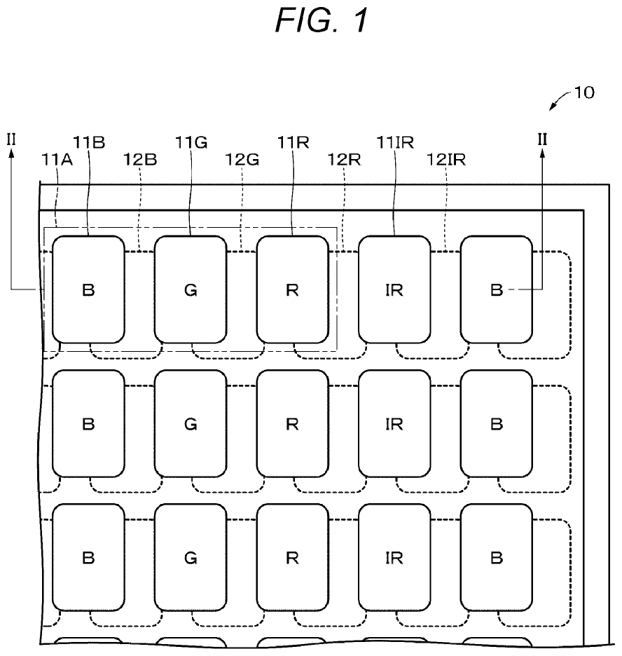

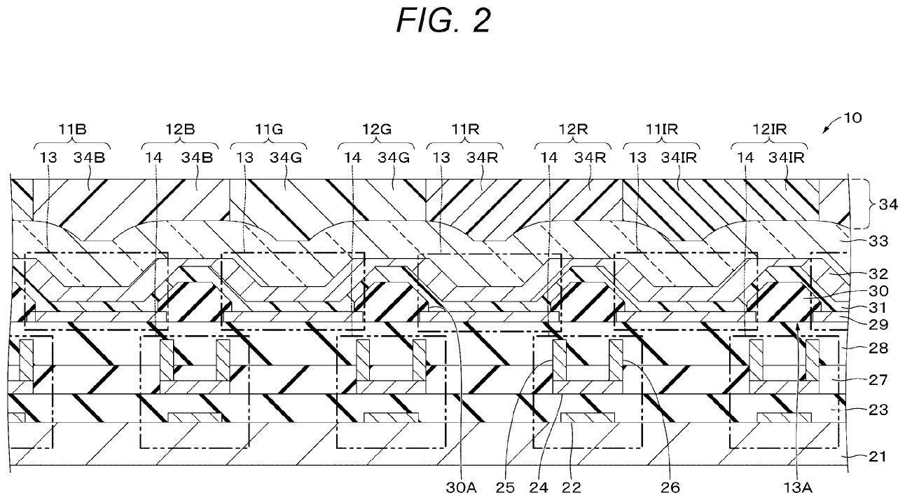

FIG. 1 is a plan view illustrating an example of a configuration of a light emitting and receiving device 10 according to a first embodiment of the present disclosure. FIG. 2 is a cross-sectional view taken along line II-II of FIG. 1. The light emitting and receiving device 10 includes a plurality of light emitting units 11B, a plurality of light emitting units 11G, a plurality of light emitting units 11R, a plurality of light emitting units 11IR, a plurality of light receiving units 12B, a plurality of light receiving units 12G, a plurality of light receiving units 12R, and a plurality of light receiving units 12IR, on a drive substrate 21.

The light emitting and receiving device 10 can both display an image and capture an image. The light emitting and receiving device 10 may be a microdisplay having an imaging function. The light emitting and receiving device 10 may be included in a virtual reality (VR) device, a mixed reality (MR) device, an augmented reality (AR) device, or the like.

The drive substrate 21 side of the light emitting and receiving device 10 is a bottom side, and a side opposite to the drive substrate 21 side of the light emitting and receiving device 10 is a top side. The light emitting and receiving device 10 has a surface (hereinafter, referred to as a “light emitting and receiving surface”) that releases and receives light on the top side. The light emitting and receiving surface has a rectangular shape. In the following description, a longer-side direction of the light emitting and receiving surface is referred to as a horizontal direction, and a shorter-side direction of the light emitting and receiving surface is referred to as a vertical direction. Furthermore, in each layer constituting the light emitting and receiving device 10, a surface on the top side of the light emitting and receiving device 10 is referred to as a first surface, and a surface on a side opposite to the bottom side of the light emitting and receiving device 10 is referred to as a second surface.

(Light Emitting Unit)

Each of the light emitting unit 11B, the light emitting unit 11G, and the light emitting unit 11R constitutes a subpixel for image display. The light emitting unit 11IR constitutes an infrared light emitting unit that causes infrared light to exit. The light emitting unit 11IR is used, for example, for line-of-sight detection or distance measurement (distance measurement between the light emitting and receiving device 10 and an object). The light emitting units 11B, 11G, 11R, and 11IR each have different peak emission wavelengths. Specifically, the light emitting units 11B, 11G, 11R, and 11IR respectively cause blue light, green light, red light, and infrared light to exit. In the following description, the light emitting units 11B, 11G, 11R, and 11IR will be referred to as light emitting units 11 in a case of being collectively referred to without being particularly distinguished.

The plurality of light emitting units 11 is two-dimensionally arranged separately, in an in-plane direction of the light emitting and receiving surface in a prescribed arrangement pattern. A combination of three neighboring light emitting units 11B, 11G, and 11R constitutes one pixel 11A. The light emitting unit 11IR is arranged adjacent to each pixel 11A at a rate of one for one pixel 11A. However, the arrangement of the light emitting units 11IR is not limited to this example, and the light emitting units 11IR may be arranged adjacent to a block of two or more pixels 11A at a rate of one for the two or more pixels 11A. The plurality of light emitting units 11B, 11G, and 11R constituting the plurality of subpixels may be arranged in a stripe pattern, for example, as illustrated in FIG. 1. The plurality of light emitting units 11IR is arranged at a prescribed cycle in the horizontal direction.

The light emitting unit 11B includes a light emitting element 13 and a blue colored layer 34B facing this light emitting element 13. The light emitting unit 11G includes a light emitting element 13 and a green colored layer 34G facing this light emitting element 13. The light emitting unit 11R includes a light emitting element 13 and a red colored layer 34R facing this light emitting element 13. The light emitting unit 11IR includes a light emitting element 13 facing this light emitting element 13 and an infrared light transmitting layer 34IR.

(Light Emitting Elements)

The light emitting element 13 is configured to be able to cause at least white light and infrared light to exit. The plurality of light emitting elements 13 is two-dimensionally arranged separately, in the in-plane direction of the light emitting and receiving surface in a prescribed arrangement pattern. An inter-element separation portion 13A is provided between adjacent light emitting elements 13. The light emitting element 13 includes a first electrode 29, an organic EL layer 31, and a second electrode 32.

(Light Receiving Unit)

Each of the light receiving units 12B, 12G, and 12R constitutes a subpixel for image capturing. The light receiving unit 12IR constitutes an infrared light receiving unit that receives infrared light. The light receiving unit 12IR is used, for example, at a time of line-of-sight detection or distance measurement (distance measurement between the light emitting and receiving device 10 and an object), together with the light emitting unit 11IR. The light receiving unit 12IR may constitute a subpixel for infrared image capturing. The light receiving units 12B, 12G, 12R, and 12IR each have different peak sensitivity wavelengths. Specifically, the light receiving units 12B, 12G, 12R, and 12IR are configured to be able to detect blue light, green light, red light, and infrared light, respectively. In the following description, the light receiving units 12B, 12G, 12R, and 12IR will be referred to as light receiving units 12 in a case of being collectively referred to without being particularly distinguished.

The plurality of light receiving units 12 is two-dimensionally arranged in the in-plane direction of the light emitting and receiving surface in a prescribed arrangement pattern. The plurality of light receiving units 12 may be arranged in a two-dimensional arrangement pattern similar to that of the plurality of light emitting units 11. A combination of three neighboring light receiving units 12B, 12G, and 12R constitutes one pixel. The light receiving unit 12IR is arranged adjacent to each pixel at a rate of one for one pixel. However, the arrangement of the light receiving unit 12IR is not limited to this example, and the light receiving unit 12IR may be arranged adjacent to a block of two or more pixels at a rate of one for the two or more pixels. The plurality of light receiving units 12B, 12G, and 12R constituting the plurality of subpixels is arranged in a stripe pattern, for example, as illustrated in FIG. 1. The plurality of light emitting units 11IR is arranged at a prescribed cycle in the horizontal direction.

The light receiving unit 12B includes a light receiving element 14 and the blue colored layer 34B covering above this light receiving element 14. The light receiving unit 12G includes a light receiving element 14 and the green colored layer 34G covering above this light receiving element 14. The light receiving unit 12R includes a light receiving element 14 and the red colored layer 34R covering above this light receiving element 14. The light receiving unit 12IR includes a light receiving element 14 and the infrared light transmitting layer 34IR covering above this light receiving element 14.

(Light Receiving Element)

The light receiving element 14 is configured to be able to detect at least white light and infrared light. Furthermore, the light receiving element 14 is configured to be able to receive external light and exit light from the light emitting element 13 located in the vicinity of this light receiving element 14. The light emitting element 13 located in the vicinity of the light receiving element 14 may be one of the light emitting elements 13 located closest to the light receiving element 14. The light receiving element 14 includes, for example, a transistor (MOS-TFT or the like) having a metal oxide semiconductor (MOS) structure. The plurality of light receiving elements 14 is located at different heights from the plurality of light emitting elements 13 in a thickness direction of the light emitting and receiving device 10. Furthermore, the plurality of light receiving elements 14 is two-dimensionally arranged in the in-plane direction of the light emitting and receiving surface in a prescribed arrangement pattern. Each light receiving element 14 faces the inter-element separation portion 13A between two adjacent light emitting elements 13.

In a case of assuming a plane that divides the light receiving element 14 into two portions, that is, a portion on one element side of two adjacent light emitting elements 13 and a portion on another element side of the two adjacent light emitting elements 13, the light receiving element 14 may have symmetry with respect to the above-described plane as illustrated in FIG. 2.

The arrangement position of each light receiving element 14 in the in-plane direction of the light emitting and receiving surface may be shifted in at least one of the horizontal direction or the vertical direction from the arrangement position of each light emitting element 13 in the in-plane direction of the light emitting and receiving surface. The light receiving element 14 includes a gate electrode 22, a gate insulating layer 23, a semiconductor layer 24, a source electrode 25, and a drain electrode 26.

(Layer Configuration)

Hereinafter, with reference to FIG. 2, an example of a layer configuration of the light emitting and receiving device 10 according to the first embodiment of the present disclosure will be described.

The light emitting and receiving device 10 includes: the drive substrate 21, a plurality of gate electrodes 22, the gate insulating layer 23, a plurality of semiconductor layers 24, a plurality of source electrodes 25, a plurality of drain electrodes 26, an interlayer insulating layer 27, a planarization layer 28, a plurality of first electrodes 29, an insulating layer 30, the organic EL layer 31, the second electrode 32, a protective layer 33, and a color filter 34. Note that the planarization layer 28 is provided as necessary, and may not be provided.

(Drive Substrate)

The drive substrate 21 is a so-called backplane. The drive substrate 21 includes, for example, a substrate, various circuits, an insulating layer, and the like (all not illustrated).

The substrate is for arranging the plurality of light emitting elements 13, the plurality of light receiving elements 14, various circuits, and the like. The substrate may be configured by, for example, a semiconductor easily formed with a transistor or the like, or may be configured by glass or resin having low moisture and oxygen permeability. Specifically, the substrate may be a semiconductor substrate, a glass substrate, a resin substrate, or the like. The semiconductor substrate includes, for example, amorphous silicon, polycrystalline silicon, monocrystalline silicon, or the like. The glass substrate includes, for example, high strain point glass, soda glass, borosilicate glass, forsterite, lead glass, quartz glass, or the like. The resin substrate includes, for example, at least one selected from a group including polymethyl methacrylate, polyvinyl alcohol, polyvinyl phenol, polyethersulfone, polyimide, polycarbonate, polyethylene terephthalate, polyethylene naphthalate, and the like.

The various circuits are provided on the first surface of the substrate. The various circuits include, for example, a drive circuit, a power supply circuit, and the like. The drive circuit drives the plurality of light emitting elements 13 and the plurality of light receiving elements 14. The power supply circuit supplies power to the plurality of light emitting elements 13 and the plurality of light receiving elements 14.

The insulating layer is provided on the first surface of the substrate so as to cover the various circuits. The insulating layer insulates the various circuits from the plurality of light receiving elements 14. Furthermore, the insulating layer planarizes the first surface of the substrate on which the various circuits are provided.

(Gate Electrode)

The plurality of gate electrodes 22 is two-dimensionally arranged on the first surface of the drive substrate 21, in a prescribed arrangement pattern such as a matrix shape. The gate electrode 22 is connected to the drive circuit. The gate electrode 22 contains, for example, a metal material such as molybdenum.

(Gate Insulating Layer)

The gate insulating layer 23 is provided on the first surface of the drive substrate 21 so as to cover the plurality of gate electrodes 22. The gate insulating layer 23 insulates between the gate electrode 22 and the semiconductor layer 24.

The gate insulating layer 23 includes, for example, at least one selected from a group including silicon oxide (SiOₓ), silicon nitride (SiNₓ), silicon oxynitride (SiOₓN_{y}), and the like.

(Semiconductor Layer)

The semiconductor layer 24 is provided on the first surface of the gate insulating layer 23 and faces the gate electrode 22. The semiconductor layer 24 has a source region, a drain region, and a channel region. The channel region is sandwiched between the source region and the drain region. The channel region is, for example, a photoactive layer that generates electron-hole pairs by incidence (irradiation) of light. The source region and the drain region are each formed by, for example, introduction (implantation) of impurities. The semiconductor layer 24 includes, for example, silicon or an oxide semiconductor. The silicon includes, for example, amorphous silicon (a-Si), polycrystalline silicon (p-Si), or microcrystalline silicon (p-Si). The oxide semiconductor includes, for example, indium gallium zinc oxide (InGaZnO (IGZO)).

(Source Electrode and Drain Electrode)

The source electrode 25 is provided on the source region of the semiconductor layer 24. The drain electrode 26 is provided on the drain region of the semiconductor layer 24. The source electrode 25 and the drain electrode 26 are separated from each other. The source electrode 25 and the drain electrode 26 are connected to the drive circuit. The source electrode 25 and the drain electrode 26 contain, for example, a metal material such as aluminum (Al).

(Interlayer Insulating Layer)

The interlayer insulating layer 27 is provided on the first surface of the gate insulating layer 23 so as to cover the plurality of semiconductor layers 24. The interlayer insulating layer 27 insulates between the light emitting element 13 and the light receiving element 14. The interlayer insulating layer 27 may have, for example, a single layer structure or a stacked structure. The interlayer insulating layer 27 may be an organic insulating layer, an inorganic insulating layer, or a stacked body thereof. The organic insulating layer includes, for example, at least one selected from a group including a polyimide-based resin, an acrylic resin, a novolac-based resin, and the like. The inorganic insulating layer includes, for example, at least one selected from a group including silicon oxide (SiO₂), silicon nitride (SiN), silicon oxynitride (SiON), and the like.

(Planarization Layer)

The planarization layer 28 is provided on the first surface of the interlayer insulating layer 27. The planarization layer 28 covers the source electrode 25 and the drain electrode 26 protruding from the first surface of the interlayer insulating layer 27, and planarizes the first surface of the interlayer insulating layer 27. The planarization layer 28 may be, for example, an organic insulating layer or an inorganic insulating layer. As the organic insulating layer, a material similar to that of the organic insulating layer of the interlayer insulating layer 27 can be exemplified. As the inorganic insulating layer, a material similar to the inorganic insulating layer of the interlayer insulating layer 27 can be exemplified.

(First Electrode)

The plurality of first electrodes 29 is two-dimensionally arranged on the first surface of the planarization layer 28, in a prescribed arrangement pattern such as a matrix shape. The first electrode 29 is an anode. When a voltage is applied between the first electrode 29 and the second electrode 32, holes are injected from the first electrode 29 into the organic EL layer 31. Adjacent first electrodes 29 are electrically separated by the insulating layer 30.

The first electrode 29 may be formed by, for example, a metal layer, or may be formed by a metal layer and a transparent conductive oxide layer. In a case where the first electrode 29 is formed by a metal layer and a transparent conductive oxide layer, the transparent conductive oxide layer is preferably provided on the organic EL layer 31 side from the viewpoint of placing a layer having a high work function adjacent to the organic EL layer 31.

The metal layer also has a function as a reflective layer that reflects light generated in the organic EL layer 31. The metal layer includes, for example, at least one metal element selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include, for example, AlNd and AlCu.

A base layer (not illustrated) may be provided adjacent to the second surface side of the metal layer. The base layer is for improving the crystal orientation of the metal layer at the time of forming the metal layer. The base layer includes, for example, at least one metal element selected from a group including titanium (Ti) and tantalum (Ta). The base layer may include the at least one metal element described above as a constituent element of an alloy.

The transparent conductive oxide layer includes a transparent conductive oxide. The transparent conductive oxide includes, for example, at least one selected from a group including a transparent conductive oxide including indium (hereinafter referred to as “indium-based transparent conductive oxide”), a transparent conductive oxide including tin (hereinafter referred to as a “tin-based transparent conductive oxide”), and a transparent conductive oxide including zinc (hereinafter referred to as a “zinc-based transparent conductive oxide”).

The indium-based transparent conductive oxide includes, for example, indium tin oxide (ITO), indium zinc oxide (IZO), indium gallium oxide (IGO), indium gallium zinc oxide (IGZO) or fluorine-doped indium oxide (IFO). Among these transparent conductive oxides, the indium tin oxide (ITO) is particularly preferable. This is because indium tin oxide (ITO) has a particularly low barrier for hole injection into the organic EL layer 31 as a work function, so that the drive voltage of the light emitting and receiving device 10 can be particularly reduced. The tin-based transparent conductive oxide includes, for example, tin oxide, antimony-doped tin oxide (ATO), or fluorine-doped tin oxide (FTC). The zinc-based transparent conductive oxide includes, for example, zinc oxide, aluminum-doped zinc oxide (AZO), boron-doped zinc oxide, or gallium-doped zinc oxide (GZO).

(Insulating Layer)

The insulating layer 30 is provided in a portion (that is, the inter-element separation portion 13A) between adjacent first electrodes 29 on the first surface of the drive substrate 21. The insulating layer 30 insulates between the adjacent first electrodes 29. The insulating layer 30 has a plurality of openings 30A. Each of the plurality of openings 30A is provided corresponding to each light emitting unit 11. More specifically, each of the plurality of openings 30A is provided on the first surface (a surface on the organic EL layer 31 side) of each first electrode 29. The first electrode 29 and the organic EL layer 31 are in contact with each other through the opening 30A. The insulating layer 30 may cover the first electrode 29 from a peripheral edge portion to a side surface (an end surface) of the first surface of this first electrode 29. In the present specification, the peripheral edge portion of the first surface refers to a region having a predetermined width from a peripheral edge of the first surface toward inside.

The insulating layer 30 may be an organic insulating layer, an inorganic insulating layer, or a stacked body thereof. The organic insulating layer includes, for example, at least one selected from a group including a polyimide-based resin, an acrylic resin, a novolac-based resin, and the like. The inorganic insulating layer includes, for example, at least one selected from a group including silicon oxide (SiOₓ), silicon nitride (SiNₓ), silicon oxynitride (SiOₓN_{y}), and the like.

(Organic EL Layer)

The organic EL layer 31 is provided between the first electrode 29 and the second electrode 32. The organic EL layer 31 is provided continuously over all the light emitting elements 13 in a light emitting and receiving region, and is a layer common to all the light emitting units 11 in the light emitting and receiving region.

The organic EL layer 31 is an example of an organic layer including a light emitting layer. The organic EL layer 31 is configured to be able to cause at least white light and infrared light to exit. The organic EL layer 31 includes a single-layer light emission unit. The organic EL layer 31 may be an organic EL layer having a one-stack structure, an organic EL layer having a two-stack structure including a two-layer light emission unit, or an organic EL layer having a structure other than these.

The organic EL layer 31 may be one including a blue light emitting layer, a green light emitting layer, a red light emitting layer, and an infrared light emitting layer as light emitting layers, may be one including a blue light emitting layer, a green light emitting layer, and a red/infrared light emitting layer, or may be one including a blue light emitting layer, a yellow light emitting layer, and an infrared light emitting layer.

In the blue light emitting layer, the green light emitting layer, the red light emitting layer, the yellow light emitting layer, and the infrared light emitting layer, when an electric field is applied, recombination of holes injected from the first electrode 29 and electrons injected from the second electrode 32 occurs, and blue light, green light, red light, yellow light, and infrared light are respectively generated. In the red/infrared light emitting layer, when an electric field is applied, recombination of holes injected from the first electrode 29 and electrons injected from the second electrode 32 occurs, and red light and infrared light are generated.

(Second Electrode)

The second electrode 32 is provided to face the plurality of first electrodes 29. The second electrode 32 is provided continuously over all the light emitting units 11 in the light emitting and receiving region, and is an electrode common to all the light emitting units 11 in the light emitting and receiving region. The second electrode 32 is a cathode. When a voltage is applied between the first electrode 29 and the second electrode 32, electrons are injected from the second electrode 32 into the organic EL layer 31. The second electrode 32 is a transparent electrode having transparency to light generated in the organic EL layer 31. The second electrode 32 preferably contains a material having as high transmissivity as possible and a small work function, in order to enhance luminous efficiency.

The second electrode 32 is formed by, for example, at least one of a metal layer or a transparent conductive oxide layer. More specifically, the second electrode 32 is formed by a single layer film of a metal layer or a transparent conductive oxide layer, or a stacked film of a metal layer and a transparent conductive oxide layer. In a case where the second electrode 32 is formed by a stacked film, the metal layer may be provided on the organic EL layer 31 side, or the transparent conductive oxide layer may be provided on the organic EL layer 31 side, but from the viewpoint of placing a layer having a low work function adjacent to the organic EL layer 31, the metal layer is preferably provided on the organic EL layer 31 side.

The metal layer includes, for example, at least one metal element selected from a group including magnesium (Mg), aluminum (Al), silver (Ag), calcium (Ca), and sodium (Na). The metal layer may include the at least one metal element described above as a constituent element of an alloy. Specific examples of the alloy include an MgAg alloy, an MgAl alloy, an AlLi alloy, and the like. The transparent conductive oxide layer includes a transparent conductive oxide. As the transparent conductive oxide, a material similar to the transparent conductive oxide of the first electrode 29 described above can be exemplified.

(Protective Layer)

The protective layer 33 is provided on the first surface of the second electrode 32, and covers the plurality of light emitting elements 13. The protective layer 33 shields the plurality of light emitting elements 13 and the plurality of light receiving elements 14 from outside air, and suppresses moisture ingress into the plurality of light emitting elements 13 from an external environment. Furthermore, in a case where the second electrode 32 includes a metal layer, the protective layer 33 may have a function of suppressing oxidation of the metal layer.

The protective layer 33 includes, for example, an inorganic material or a polymer resin having low hygroscopicity. The protective layer 33 may have a single layer structure or a multilayer structure. In a case where a thickness of the protective layer 33 is increased, it is preferable to have a multilayer structure. This is for alleviating the internal stress in the protective layer 33. The inorganic material includes, for example, at least one selected from a group including silicon oxide (SiOₓ), silicon nitride (SiNₓ), silicon oxynitride (SiOₓN_{y}), titanium oxide (TiOₓ), aluminum oxide (AlOₓ), and the like. The polymer resin includes, for example, at least one selected from a group including a thermosetting resin, an ultraviolet curable resin, and the like.

(Color Filter)

The color filter 34 is provided on the first surface of the protective layer 33. The color filter 34 is an on-chip color filter (OCCF). The color filter 34 includes, for example, a plurality of blue colored layers 34B, a plurality of green colored layers 34G, a plurality of red colored layers 34R, and a plurality of infrared light transmitting layers 341R. The blue, green, and red are examples of a first color, a second color, a third color, respectively. The plurality of colored layers 34B, 34G, and 34R individually faces some of the plurality of light emitting elements 13. The plurality of infrared light transmitting layers 341R individually faces the rest of the plurality of light emitting elements 13.

The blue colored layer 34B is provided to face the light emitting element 13 constituting the light emitting unit 11B. The colored layer 34B covers above the light receiving element 14 located in the vicinity of the light emitting element 13 facing this colored layer 34B. For example, the colored layer 34B may cover one of the light receiving elements 14 closest to the light emitting element 13 facing this colored layer 34B.

The green colored layer 34G is provided to face the light emitting element 13 constituting the light emitting unit 11G. The colored layer 34G covers above the light receiving element 14 located in the vicinity of the light emitting element 13 facing this colored layer 34G. For example, the colored layer 34G may cover one of the light receiving elements 14 closest to the light emitting element 13 facing this colored layer 34G.

The red colored layer 34R is provided to face the light emitting element 13 constituting the light emitting unit 11R. The colored layer 34R covers above the light receiving element 14 located in the vicinity of the light emitting element 13 facing this colored layer 34R. For example, the colored layer 34R may cover one of the light receiving elements 14 closest to the light emitting element 13 facing this colored layer 34R.

The infrared light transmitting layer 34IR is provided to face the light emitting element 13 constituting the light emitting unit 11IR. The infrared light transmitting layer 34IR covers above the light receiving element 14 located in the vicinity of the light emitting element 13 facing this infrared light transmitting layer 34IR. For example, the infrared light transmitting layer 34IR may cover one of the light receiving elements 14 closest to the light emitting element 13 facing this infrared light transmitting layer 34IR.

The blue colored layer 34B transmits blue light included in external light or included in exit light from the light emitting element 13, and absorbs light other than the blue light. The green colored layer 34G transmits green light included in external light or included in exit light from the light emitting element 13, and absorbs light other than the green light. The red colored layer 34R transmits red light included in external light or included in exit light from the light emitting element 13, and absorbs light other than the red light. The infrared light transmitting layer 34IR transmits infrared light included in external light or included in exit light from the light emitting element 13, and absorbs light other than the infrared light.

[Circuit Configuration of Light Emitting and Receiving Device]

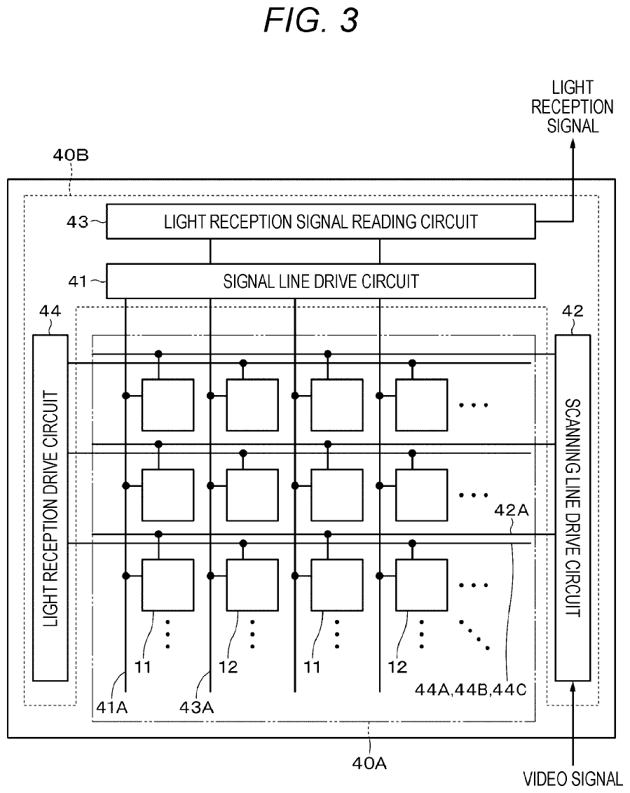

FIG. 3 is a schematic diagram illustrating an example of a circuit configuration of the light emitting and receiving device 10 according to the first embodiment of the present disclosure. The light emitting and receiving device 10 includes a light emitting and receiving region 40A and a peripheral region 40B provided on a peripheral edge of the light emitting and receiving region 40A. In the light emitting and receiving region 40A, a plurality of light emitting units 11 and a plurality of light receiving units 12 are two-dimensionally arranged. The peripheral region 40B is provided with a signal line drive circuit 41 and a scanning line drive circuit 42, which are drivers for video display. Furthermore, the peripheral region 40B is provided with a light reception signal reading circuit 43 and a light reception drive circuit 44, which are drivers for imaging.

The signal line drive circuit 41 and the scanning line drive circuit 42 are circuits for performing light emission driving. Specifically, by writing a video signal voltage based on a video signal into the selected light emitting unit 11 while sequentially selecting the plurality of light emitting units 11, the light emission driving is performed on the plurality of light emitting units 11.

The signal line drive circuit 41 supplies a signal voltage of a video signal corresponding to luminance information supplied from a signal supply source (not illustrated) to the light emitting unit 11 selected via a signal line 41A. The scanning line drive circuit 42 includes a shift register or the like that sequentially shifts (transfers) a start pulse in synchronization with an input clock pulse. When writing the video signal into each of the light emitting units 11, the scanning line drive circuit 42 scans them row by row, and sequentially supplies a scanning signal to each scanning line 42A.

The light reception signal reading circuit 43 and the light reception drive circuit 44 are circuits for performing light reception driving. The light reception drive circuit 44 sequentially applies a light reception control pulse to each of a plurality of scanning lines 44A, a plurality of power supply lines 44B, and a plurality of gate lines 44C. As a result, a light reception operation (a light detection operation) of each light receiving unit 112 is controlled. Note that, in FIG. 3, the scanning line 44A, the power supply line 44B, and the gate line 44C are simplified by one line. The light reception signal reading circuit 43 is a circuit for reading out each light reception signal output from the plurality of signal lines 43A as light reception signal lines.

[Configuration of Light Emission and Reception Processing Device]

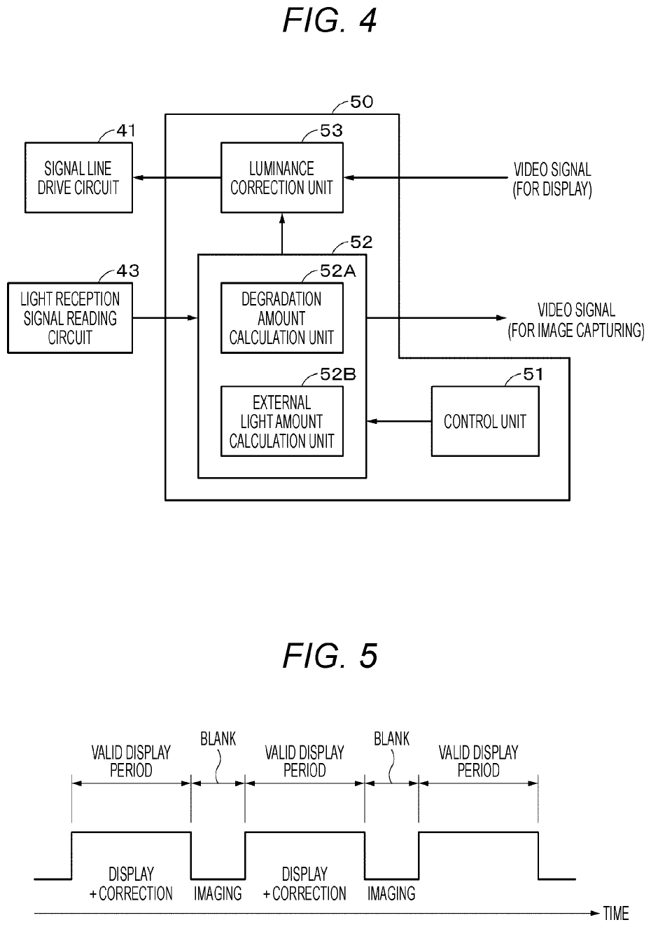

FIG. 4 is a block diagram illustrating an example of a configuration of a light emission and reception processing device 50. The light emitting and receiving device 10 further includes the light emission and reception processing device 50. The light emission and reception processing device 50 includes a control unit 51, a calculation unit 52, and a luminance correction unit 53.

(Control Unit)

The control unit 51 controls light emission and light reception operations of the light emitting and receiving device 10. The control unit 51 controls driving of the plurality of light emitting elements 13 (that is, the plurality of light emitting units 11) by controlling the signal line drive circuit 41 and the scanning line drive circuit 42. The control unit 51 controls driving of the plurality of light receiving elements 14 (that is, the plurality of light receiving units 12) by controlling the light reception signal reading circuit 43 and the light reception drive circuit 44.

Table 1 illustrates an operation example of the control unit 51.

TABLE 1

| | Light | Light | |
|---|---|---|---|
| | reception ON | reception ON | |
| | (Detection of | (Detection of | Light |
| | exit light) | external light) | reception OFF |
| Light | (1) Image is | (1) Image is | (1) Image is |
| emission | displayed | displayed | displayed |
| ON | (2) | (3) External | |
| | Degradation of | light is | |
| | light emitting | detected, and | |
| | element | light emission | |
| | (degradation, | intensity of | |
| | burn-in, and | light emitting | |
| | the like) is | element is | |
| | detected and | adjusted | |
| | corrected | (4) Image is | |
| | | captured | |
| | | (camera) | |
| Light | No control | (4) Image is | No control |
| emission | mode | captured | mode |
| OFF | | (camera) | |

In Table 1, “light emission ON” means performing an operation of driving the light emitting element 13 to cause light to exit from the light emitting element 13. Furthermore, “light reception ON” means performing an operation of driving the light receiving element 14 to read out a light reception signal.

The control unit 51 has, for example, a first operation mode, a second operation mode, and a third operation mode, and performs control according to each operation mode. In the first operation mode, luminance correction of the light emitting element 13 is performed on the basis of a degradation amount of the light emitting element 13. In the second operation mode, luminance correction of the light emitting element 13 is performed on the basis of an external light amount. In the third operation mode, imaging is performed. The control unit 51 may further include a fourth operation mode. In the fourth operation mode, line-of-sight detection of a user is performed.

(Calculation Unit)

The calculation unit 52 calculates a degradation amount of the light emitting element 13 or an external light amount on the basis of the control of the control unit 51, and outputs the calculation result to the luminance correction unit 53. The calculation unit 52 includes a degradation amount calculation unit 52A and an external light amount calculation unit 52B. An operation of the calculation unit 52 differs depending on the operation mode. In the first operation mode, the degradation amount calculation unit 52A calculates a degradation amount of the light emitting element 13 on the basis of the control of the control unit 51, and controls the luminance correction unit 53 on the basis of the calculation result. In the second operation mode, the external light amount calculation unit 52B calculates an external light amount on the basis of the control of the control unit 51, and controls the luminance correction unit 53 on the basis of the calculation result. In the third mode, neither the degradation amount calculation unit 52A nor the external light amount calculation unit 52B performs the calculation operation.

(Luminance Correction Unit)

The luminance correction unit 53 adjusts a luminance level of a video signal on the basis of a calculation result output from the calculation unit 52, and outputs the video signal to the signal line drive circuit 41. The correction control of the luminance correction unit 53 may be feedback control.

[Operation of Light Emitting and Receiving Device]

FIG. 5 is a time chart for explaining an example of an operation of the light emission and reception processing device 50. The control unit 51 controls driving of the plurality of light emitting elements 13 so as to alternately repeat a display valid period and a blanking period. In the display valid period, the control unit 51 sets the operation mode to the first operation mode, displays an image by the plurality of light emitting units 11, and performs luminance correction of the plurality of light emitting units 11 (that is, luminance correction of the plurality of light emitting elements 13) on the basis of a calculation result of the degradation amount of the plurality of light emitting elements 13. Whereas, in the blanking period, the control unit 51 sets the operation mode to the third operation mode, and performs imaging by the plurality of light receiving units 12.

Note that, in the blanking period, the control unit 51 may set the operation mode to the second operation mode, and perform luminance correction of the plurality of light emitting units 11 (that is, luminance correction of the plurality of light emitting elements 13) on the basis of a calculation result of an external light amount.

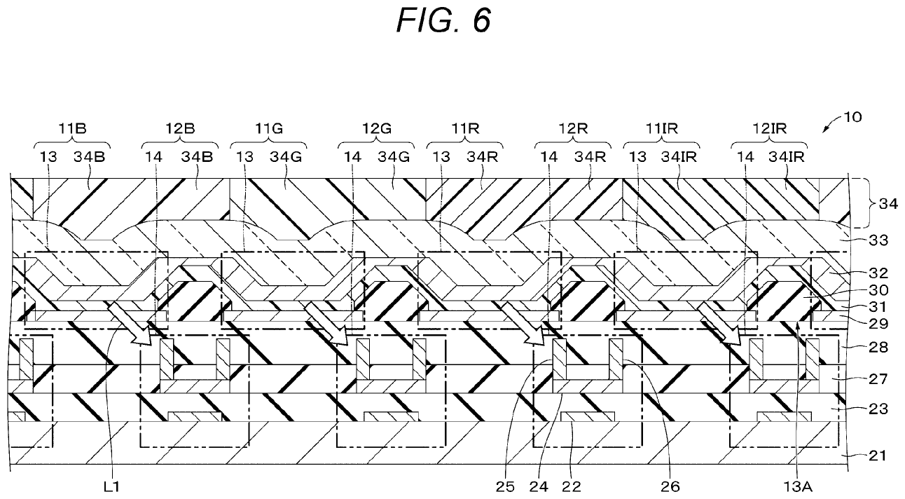

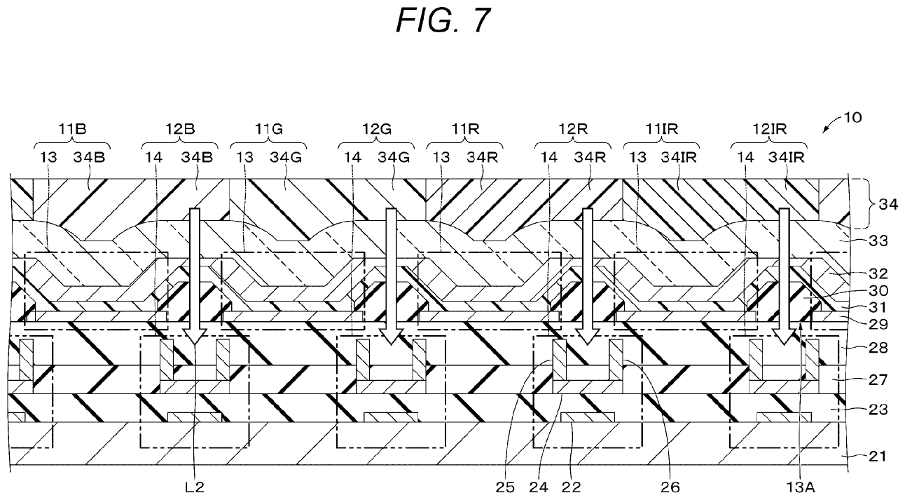

Hereinafter, with reference to FIGS. 6 and 7, an example of an operation of the light emission and reception processing device 50 in each operation mode will be described.

(First Operation Mode)

In a case where the operation mode is set to the first operation mode, the light emission and reception processing device 50 operates as follows. The control unit 51 controls the signal line drive circuit 41 and the scanning line drive circuit 42 to drive the plurality of light emitting elements 13 to emit light. At this time, exit light L1 caused to exit from the plurality of light emitting elements 13 is received by the plurality of light receiving elements 14 as illustrated in FIG. 6.

The control unit 51 drives the light reception signal reading circuit 43 and the light reception drive circuit 44, and reads out a light reception signal corresponding to a light reception amount of the exit light L1, from the plurality of light receiving elements 14 via the light reception signal reading circuit 43. The degradation amount calculation unit 52A calculates a degradation amount of the plurality of light emitting elements 13 on the basis of light reception signals supplied from the plurality of light receiving elements 14 via the light reception signal reading circuit 43, and outputs a calculation result to the luminance correction unit 53. On the basis of the calculation result output from the degradation amount calculation unit 52A, the luminance correction unit 53 increases a luminance level of a video signal such that a level of the light reception signal supplied from the light receiving element 14 falls within a prescribed range, and outputs the video signal to the signal line drive circuit 41. The correction control of the luminance correction unit 53 may be feedback control.

(Second Operation Mode)

In a case where the operation mode is set to the second operation mode, the light emission and reception processing device 50 operates as follows. As illustrated in FIG. 7, the plurality of light receiving elements 14 receives external light L2. The control unit 51 drives the light reception signal reading circuit 43 and the light reception drive circuit 44, and reads out a light reception signal corresponding to a light reception amount of the external light L2, from the plurality of light receiving elements 14 via the light reception signal reading circuit 43. The external light amount calculation unit 52B calculates an external light amount on the basis of light reception signal supplied via the light reception signal reading circuit 43, and outputs a calculation result to the luminance correction unit 53. The luminance correction unit 53 adjusts a luminance level of a video signal on the basis of the calculation result output from the external light amount calculation unit 52B, and outputs the video signal to the signal line drive circuit 41.

(Third Operation Mode)

In a case where the operation mode is set to the third operation mode, the light emission and reception processing device 50 operates as follows. As illustrated in FIG. 7, the plurality of light receiving elements 14 receives external light L2. The control unit 51 drives the light reception signal reading circuit 43 and the light reception drive circuit 44, and reads out a light reception signal corresponding to a light reception amount of the external light L2, from the plurality of light receiving elements 14 via the light reception signal reading circuit 43. The degradation amount calculation unit 52A and the external light amount calculation unit 52B output a light reception signal supplied from the light reception signal reading circuit 43 to an external device, without performing any of the above-described degradation amount calculation operation and the above-described external light amount calculation operation.

(Fourth Mode)

In a case where the operation mode is set to the fourth operation mode, the light emission and reception processing device 50 operates as follows. The control unit 51 causes exit light to exit from the plurality of light emitting units 11, by controlling the signal line drive circuit 41 and the scanning line drive circuit 42 to drive the plurality of light emitting elements 13. A pupil is irradiated with this exit light, and reflected light is received by the plurality of light receiving elements 14.

The control unit 51 drives the light reception signal reading circuit 43 and the light reception drive circuit 44, reads out a light reception signal corresponding to a light reception amount from the plurality of light receiving elements 14 via the light reception signal reading circuit 43, and acquires an image of the pupil. The control unit 51 detects a line-of-sight of the user on the basis of the acquired image. Note that the image acquired by the control unit 51 may be output to an external device, and the external device having received the image may perform the line-of-sight detection. As a method of detecting the line-of-sight from the image, a known method can be used.

[Method for Manufacturing Light Emitting and Receiving Device]

Hereinafter, an example of a method for manufacturing the light emitting and receiving device 10 according to the first embodiment of the present disclosure will be described.

First, a metal layer is formed on the first surface of the drive substrate 21 by, for example, a sputtering method, and then the metal layer is patterned by, for example, a photolithography technique and an etching technique. As a result, the plurality of gate electrodes 22 is formed. Next, the gate insulating layer 23 is formed on the first surface of the drive substrate 21 so as to cover the plurality of gate electrodes 22 by, for example, a chemical vapor deposition (CVD) method.

Next, a semiconductor layer is formed on the first surface of the gate insulating layer 23 by, for example, a CVD method or a sputtering method, and then a plurality of source regions, a plurality of drain regions, and a plurality of channel regions are formed in the semiconductor layer by, for example, doping or the like. Next, the semiconductor layer is patterned by, for example, a photolithography technique and an etching technique. As a result, the plurality of semiconductor layers 24 is obtained. Next, a metal layer is formed on the first surface of the gate insulating layer 23 so as to cover the plurality of semiconductor layers 24 by, for example, a sputtering method, and then the metal layer is patterned by, for example, a photolithography technique and an etching technique. As a result, the plurality of source electrodes 25 and the plurality of drain electrodes 26 are formed.

Next, the interlayer insulating layer 27 is formed on the first surface of the gate insulating layer 23 so as to cover the plurality of semiconductor layers 24 by, for example, a chemical vapor deposition (CVD) method. Next, an inorganic insulating layer is formed on the first surface of the interlayer insulating layer 27 by, for example, a CVD method, and then a surface of the inorganic insulating layer is polished and planarized by, for example, chemical mechanical polishing (CMP) or the like. As a result, the planarization layer 28 is formed.

Next, a metal layer is formed on the first surface of the planarization layer 28 by, for example, a sputtering method, and then the metal layer is patterned using, for example, a photolithography technique and an etching technique. As a result, the plurality of first electrodes 29 is formed. Next, the insulating layer 30 is formed on the first surface of the planarization layer 28 so as to cover the plurality of first electrodes 29 by, for example, a CVD method. Next, the opening 30A is individually formed in a portion of the insulating layer 30 located on the first surface of each of the first electrodes 29 by, for example, a photolithography technique and a dry etching technique.

Next, the organic EL layer 31 is formed on the first surfaces of the plurality of first electrodes 29 and the insulating layer 30 by, for example, a vapor deposition method. Next, the second electrode 32 is formed on the first surface of the organic EL layer 31 by, for example, a vapor deposition method or a sputtering method. As a result, the plurality of light emitting elements 13 is formed on the first surface of the planarization layer 28. Next, the protective layer 33 is formed on the first surface of the second electrode 32 by, for example, a CVD method or a vapor deposition method, and then the color filter 34 is formed on the first surface of the protective layer 33 by, for example, photolithography. In this way, the light emitting and receiving device 10 illustrated in FIG. 2 is obtained.

[Action and Effect]

As described above, the light emitting and receiving device 10 according to the first embodiment includes the plurality of light emitting elements 13 and the plurality of light receiving elements 14. The plurality of light emitting elements 13 is two-dimensionally arranged separately. The plurality of light receiving elements 14 is two-dimensionally arranged at a height different from a height of the plurality of light emitting elements 13, and each light receiving element 14 faces the inter-element separation portion 13A between the light emitting elements 13. As a result, light having exited from the light emitting element 13 can be caused to exit to outside without being hindered by the light receiving element 14, and light from outside can be received without being hindered by the light emitting element 13. Therefore, both exit of light to outside by the light emitting element 13 and reception of light from outside by the light receiving element 14 can be performed. That is, both display and imaging can be performed. Furthermore, the light receiving element 14 can also receive exit light from the light emitting element 13. That is, a degradation amount of the light emitting element 13 can be detected.

The blue colored layer 34B covers the light emitting element 13 and the light receiving element 14 located in the vicinity of this light emitting element 13. The green colored layer 34G covers the light emitting element 13 and the light receiving element 14 located in the vicinity of this light emitting element 13. The red colored layer 34G covers the light emitting element 13 and the light receiving element 14 located in the vicinity of this light emitting element 13. As a result, blue light, green light, and red light can be caused to exit, and blue light, green light, and red light can be received. Therefore, a full-color image can be displayed, and a full-color image can be captured.

In the light emitting and receiving device 10 according to the first embodiment, the infrared light transmitting layer 34IR covers the light emitting element 13 and the light receiving element 14 located in the vicinity of this light emitting element 13. As a result, it is possible to irradiate the pupil with infrared light and receive reflected light. Therefore, line-of-sight detection can be performed by using infrared light.

In the light emitting and receiving device 10 according to the first embodiment, since each light receiving element 14 is arranged to face the inter-element separation portion 13A between the light emitting elements 13, both functions of a characteristic detection (luminance correction) function and an external light detection (imaging) function of the light emitting element 13 can be achieved.

In the light emitting and receiving device 10 according to the first embodiment, line-of-sight detection can be performed by using the light receiving element 14 as a camera, in a period in which the light emitting element 13 is inactive (a period not used for display, such as blanking).

In the light emitting and receiving device 10 according to the first embodiment, since the plurality of light emitting units 11 for image display and the plurality of light receiving units 12 for image capturing are arranged in the same region, a space for separately arranging an imaging element, a camera, or the like is unnecessary. Therefore, the device can be downsized.

In the light emitting and receiving device 10 according to the first embodiment, a display optical axis (an optical axis perpendicular to a display surface) and an imaging optical axis (an optical axis perpendicular to an imaging surface) coincide with each other, so that there is no need to design a system according to the arrangement of the imaging element, the camera, or the like.

In the light emitting and receiving device 10 according to the first embodiment, the plurality of light emitting units 11 can also serve as a light source of the plurality of light receiving units 12 (imaging elements). For example, in a case where the plurality of light emitting units 11IR is used as a light source, infrared light caused to exit from the plurality of light emitting units 11IR is invisible to a human, does not disturb a view, and passes through a melanin pigment of the eye, so that it is possible to capture an image more clearly.

In the light emitting and receiving device 10 according to the first embodiment, an RGB image (the plurality of light emitting units 11R, 11G, and 11B) and an IR image (the plurality of light emitting units 11IR) can be used for line-of-sight detection, which is advantageous for detection accuracy. In a case where the plurality of light emitting units 11 as a light source appears in the eyes and the line-of-sight detection accuracy is lowered, light emitting positions of the plurality of light emitting units 11 that causes light to exit can be changed.

### 2 Second Embodiment

[Configuration of Light Emitting and Receiving Device]

In the first embodiment described above, a description has been given to the light emitting and receiving device 10 using a method of combining the organic EL layer 31 that emits white light and the color filter 34, as a coloring method. In a second embodiment, a light emitting and receiving device using a separate coloring method of RGB as a coloring method will be described.

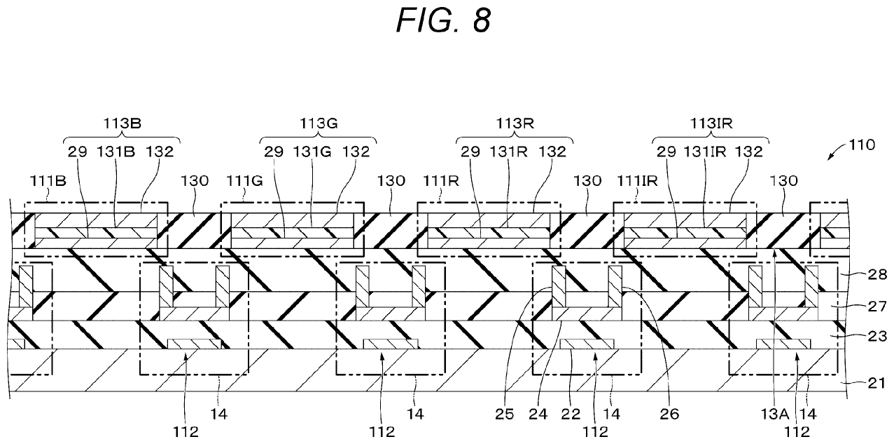

FIG. 8 is a cross-sectional view illustrating an example of a configuration of a light emitting and receiving device 110 according to the second embodiment of the present disclosure. The light emitting and receiving device 110 includes a plurality of light emitting units 111B, 111G, 111R, and 111IR and a plurality of light receiving units 112, instead of the plurality of light emitting units 11B, 11G, 11R, and 11IR and the plurality of light receiving units 12B, 12G, 12R, and 121R (see FIG. 2). Furthermore, the light emitting and receiving device 110 includes an insulating layer 130, a plurality of organic EL layers 131B, 131G, 131R, and 1311R, and a plurality of second electrodes 132, instead of the insulating layer 30, the organic EL layer 31, and the second electrode 32 (see FIG. 2). In the second embodiment, an example will be described in which the light emitting and receiving device 110 includes the plurality of second electrodes 132 instead of one second electrode 32, but the light emitting and receiving device 110 may include one second electrode 32.

The light emitting and receiving device 110 may include a protective layer 33 and a color filter 34 similarly to the first embodiment, or may not include the protective layer 33 and the color filter 34 as illustrated in FIG. 8. Note that, in the second embodiment, same reference numerals are given to parts similar to those of the first embodiment, and the description thereof will be omitted.

(Light Emitting Unit)

The light emitting unit 111B includes a light emitting element 113B. The light emitting element 113B is configured to be able to cause blue light to exit. The light emitting element 113B includes a first electrode 29, the organic EL layer 131B, and the second electrode 132 in this order.

The light emitting unit 111G includes a light emitting element 113G. The light emitting element 113G is configured to be able to cause green light to exit. The light emitting element 113G includes a first electrode 29, the organic EL layer 131G, and the second electrode 132 in this order.

The light emitting unit 111R includes a light emitting element 113R. The light emitting element 113R is configured to be able to cause red light to exit. The light emitting element 113R includes a first electrode 29, the organic EL layer 131R, and the second electrode 132 in this order.

The light emitting unit 11IR includes a light emitting element 1131R. The light emitting element 1131R is configured to be able to cause infrared light to exit. The light emitting element 1131R includes a first electrode 29, the organic EL layer 131IR, and the second electrode 132 in this order.

The light emitting elements 113B, 113G, and 113R are examples of visible light emitting elements that cause visible light to exit. The light emitting element 1131R is an example of an infrared light emitting element that causes infrared light to exit. In the following description, the light emitting element 113B, the light emitting element 113G, the light emitting element 113R, and the light emitting element 1131R are referred to as light emitting elements 113 in a case of being collectively referred to without being particularly distinguished. Similarly, the organic EL layers 131B, 131G, 131R, and 131IR are referred to as organic EL layers 131 in a case of being collectively referred to without being particularly distinguished.

Arrangement of the plurality of light emitting elements 113 is similar to the arrangement of the plurality of light emitting elements 13 in the first embodiment.

(Light Receiving Unit)

The light receiving unit 112 includes a light receiving element 14. The plurality of light receiving units 112 may include: a plurality of light receiving units configured to be able to receive blue light; a plurality of light receiving units configured to be able to receive green light; a plurality of light receiving units configured to be able to receive red light; and a plurality of light receiving units configured to be able to receive infrared light.

(Insulating Layer)

The insulating layer 130 is provided between adjacent light emitting elements 113, and separates between the adjacent light emitting elements 113. A material of the insulating layer 130 is similar to the material of the insulating layer 30 in the first embodiment.

(Organic EL Layer)

The organic EL layer 131B is provided between the first electrode 29 and the second electrode 132 included in the light emitting unit 111B. The organic EL layer 131B is configured to be able to emit blue light. The organic EL layer 131B is an example of an organic layer including a blue light emitting layer. The organic EL layer 131B has a configuration in which, for example, a hole injection layer, a hole transport layer, the blue light emitting layer, an electron transport layer, and an electron injection layer are layered in this order from the first electrode 29 toward the second electrode 132.

The organic EL layer 131G is provided between the first electrode 29 and the second electrode 132 included in the light emitting unit 111G. The organic EL layer 131G is configured to be able to emit green light. The organic EL layer 131G is an example of an organic layer including a green light emitting layer. The organic EL layer 131G has a configuration in which, for example, a hole injection layer, a hole transport layer, the green light emitting layer, an electron transport layer, and an electron injection layer are layered in this order from the first electrode 29 toward the second electrode 132.

The organic EL layer 131R is provided between the first electrode 29 and the second electrode 132 included in the light emitting unit 111R. The organic EL layer 131R is configured to be able to emit red light. The organic EL layer 131R is an example of an organic layer including a red light emitting layer. The organic EL layer 131R has a configuration in which, for example, a hole injection layer, a hole transport layer, the red light emitting layer, an electron transport layer, and an electron injection layer are layered in this order from the first electrode 29 toward the second electrode 132.

The organic EL layer 131IR is provided between the first electrode 29 and the second electrode 132 included in the light emitting unit 111IR. The organic EL layer 131IR is configured to be able to emit infrared light. The organic EL layer 131IR is an example of an organic layer including an infrared light emitting layer. The organic EL layer 131IR has a configuration in which, for example, a hole injection layer, a hole transport layer, the infrared light emitting layer, an electron transport layer, and an electron injection layer are layered in this order from the first electrode 29 toward the second electrode 132.

(Second Electrode)

The plurality of second electrodes 132 is two-dimensionally arranged in an in-plane direction of a light emitting and receiving surface in a prescribed arrangement pattern. The second electrode 132 faces the first electrode 29 with the organic EL layer 131 interposed in between. A function, a layer configuration, a material, and the like of the second electrode 132 are similar to the function, the layer configuration, the material, and the like of the second electrode 32 in the first embodiment.

[Action and Effect]

As described above, the light emitting and receiving device 110 according to the second embodiment includes the plurality of light emitting elements 113 and the plurality of light receiving elements 14. The plurality of light emitting elements 113 is two-dimensionally arranged, the plurality of light receiving elements 14 is two-dimensionally arranged at a height different from a height of the plurality of light emitting elements 13, and each light receiving element 14 faces an inter-element separation portion 13A between the light emitting elements 113. Therefore, similarly to the light emitting and receiving device 10 according to the first embodiment, both exit of light to outside by the light emitting element 113 and reception of light from outside by the light receiving element 14 can be performed. That is, both display and imaging can be performed. Furthermore, the light receiving element 14 can also receive exit light from the light emitting element 113. That is, a degradation amount of the light emitting element 113 can be detected.

### 3 Modification

[Modification 1]

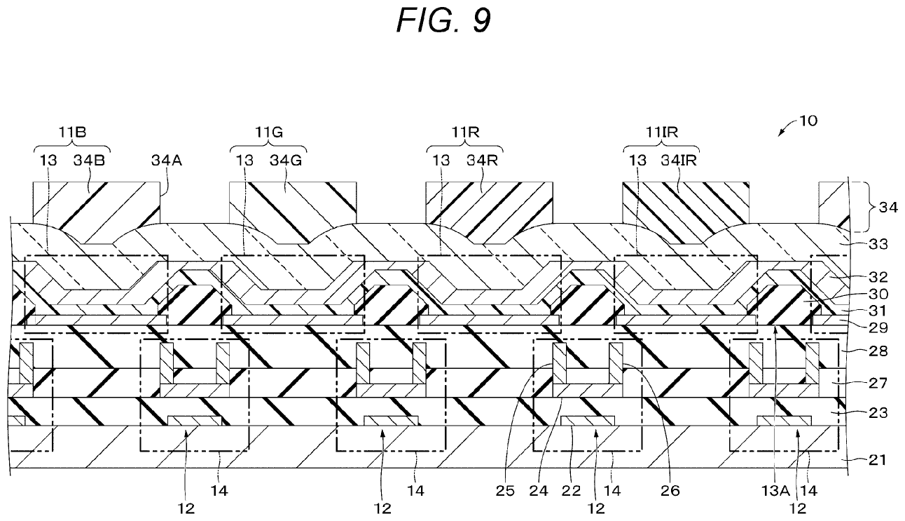

In the first embodiment described above, an example has been described in which each of the colored layers 34B, 34G, and 34R and the infrared light transmitting layer 34IR covers the light emitting element 13 and the light receiving element 14 located in the vicinity of this light emitting element 13, but the configuration of the color filter 34 is not limited thereto. For example, as illustrated in FIG. 9, each of the colored layers 34B, 34G, and 34R and the infrared light transmitting layer 34IR may not cover above the light receiving element 14 located in the vicinity of the light emitting element 13. More specifically, the color filter 34 may have a plurality of openings 34A, and each of the plurality of openings 34A may be provided to face each light receiving element 14. In this case, the light receiving unit 12 includes the light receiving element 14.

In the light emitting and receiving device 10 according to Modification 1, it is possible to capture a single color image by receiving external light with the plurality of light receiving units 12. Furthermore, since the light receiving elements 14 each are not covered with the colored layers 34B, 34G, and 34R and the infrared light transmitting layer 34IR, detection sensitivity of the light emitting and receiving device 10 can be improved.

[Modification 2]

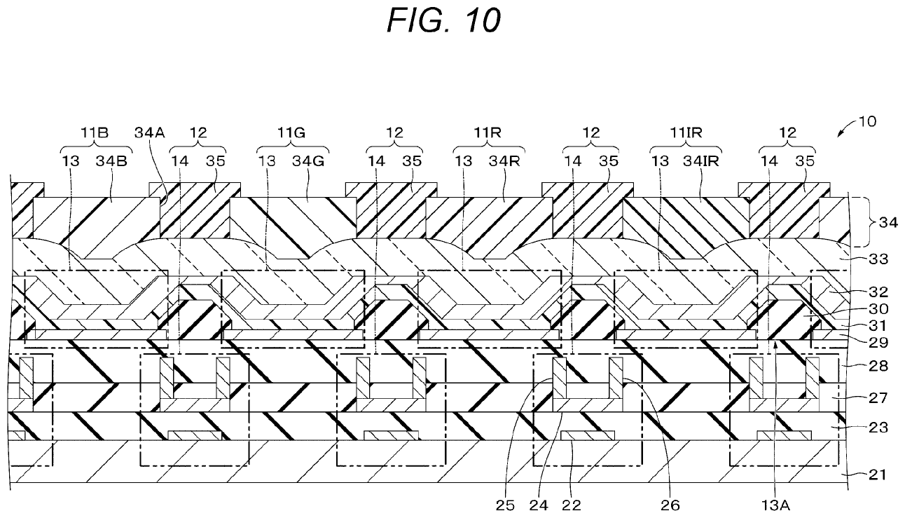

In Modification 1 described above, an example has been described in which the color filter 34 has the plurality of openings 34A. However, as illustrated in FIG. 10, a plurality of spectral layers 35 each provided in the plurality of openings 34A may be further provided. In this case, each of the plurality of spectral layers 35 is provided to face each light receiving element 14. The light receiving element 14 and the spectral layer 35 constitute the light receiving unit 12. The plurality of spectral layers 35 preferably has spectral characteristics suitable for the light receiving unit 12. The spectral layer 35 may be a colored layer of a predetermined color, or may be an infrared light transmitting layer that transmits infrared light and absorbs light other than the infrared light. The plurality of spectral layers may include a plurality of colored layers and a plurality of infrared light transmitting layers. The plurality of colored layers may include a plurality of blue colored layers, a plurality of green colored layers, and a plurality of red colored layers, or may include a plurality of colored layers of a single color. The plurality of colored layers may be those used in a color filter of an image sensor.

The color filter 34 may include a plurality of colored layers of a single color (for example, a plurality of colored layers 34G) instead of the plurality of colored layers 34B, 34G, and 34R, and the plurality of spectral layers may include a plurality of blue colored layers, a plurality of green colored layers, and a plurality of red colored layers. In this case, an image can be displayed in a single color (for example, green), and an image can be captured in full colors of blue, green, and red. Furthermore, since the color filter 34 includes the plurality of colored layers of the single color, resolution of the color of the colored layer of the single color can be improved.

The color filter 34 may include a plurality of colored layers 34B, 34G, and 34R, and the plurality of spectral layers may include a plurality of colored layers of a single color (for example, a plurality of colored layers 34G). In this case, an image can be displayed in full colors of blue, green, and red, and an image can be captured in a single color (for example, green). Furthermore, since the plurality of spectral layers includes the plurality of colored layers of the single color, resolution of the color of the colored layer of the single color can be improved.

[Modification 3]

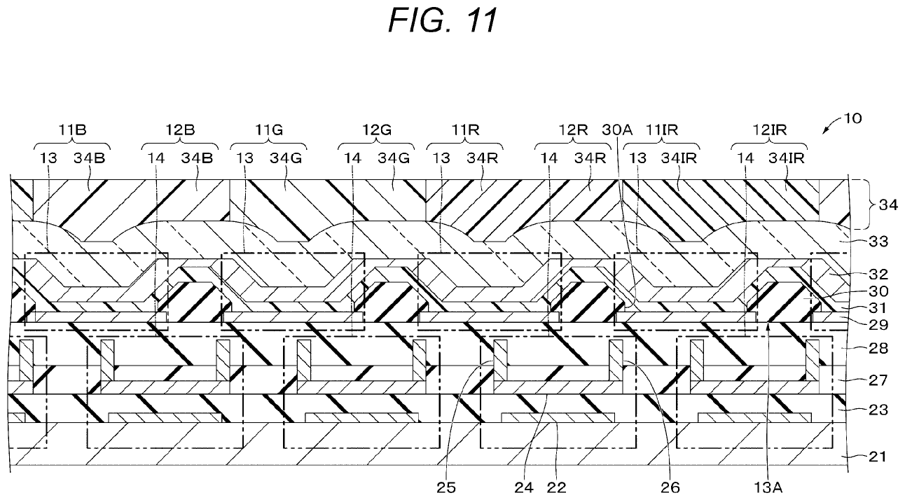

In the first and second embodiments described above, an example has been described in which a center position of the light receiving element 14 coincides with a midpoint between two adjacent light emitting elements 13 in the in-plane direction of the light emitting and receiving surface. However, as illustrated in FIG. 11, the center position of the light receiving element 14 may be shifted from the midpoint between the two adjacent light emitting elements 13 in the in-plane direction of the light emitting and receiving surface. That is, the light receiving element 14 may be arranged biased to one side of the two adjacent light emitting elements 13 in the in-plane direction of the light emitting and receiving surface. In this case, from the viewpoint of improving sensitivity of the light receiving element 14, a part of a light receiving region of the light receiving element 14 is preferably located immediately below the light emitting element 13 on the one side described above.

In the light emitting and receiving device 10 according to Modification 3, in a case where light amounts of exit light from two adjacent light emitting elements 13 are the same, an amount of light received from one of the two light emitting elements 13 described above is larger than an amount of light received from another one of the two light emitting elements 13 described above. Therefore, on the basis of the light reception amount (a light reception signal), the control unit 51 can determine which of the above-described two light emitting elements 13 the light has been incident from.

[Modification 4]

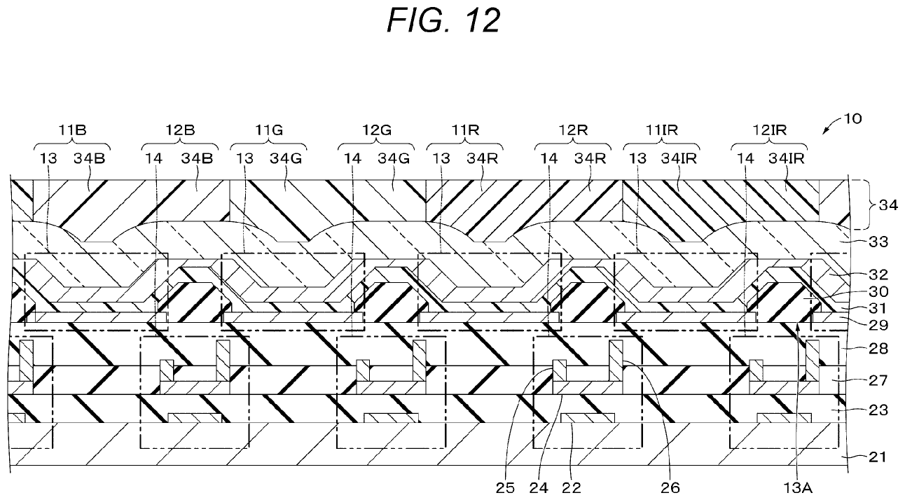

In the first and second embodiments described above, an example has been described in which the light receiving element 14 has asymmetry with respect to a plane, in a case of assuming the plane in which the light receiving element 14 is divided into two portions, that is, a portion on one side of two adjacent light emitting elements 13 and a portion on another side of the two adjacent light emitting elements 13. However, the light receiving element may have asymmetry with respect to the plane. The asymmetry is, for example, asymmetry of a structure of the light receiving element 14. Examples of the asymmetry of the structure include at least one selected from, for example, a group including asymmetry of an electrode, asymmetry of a wiring density, asymmetry of a doping concentration of a light detection unit, asymmetry of arrangement of an electrode, and the like. FIG. 12 illustrates an example in which heights of the source electrode 25 and the drain electrode 26 are asymmetric with respect to the plane described above.

In the light emitting and receiving device 10 according to Modification 4, light reception sensitivity is different between a portion on one side of two adjacent light emitting elements 13 and a portion on another side of the two adjacent light emitting elements 13. Therefore, on the basis of a signal level output from the light receiving element 14, the control unit 51 can determine which of the above-described two light emitting elements 13 the light has been incident from.

[Modification 5]

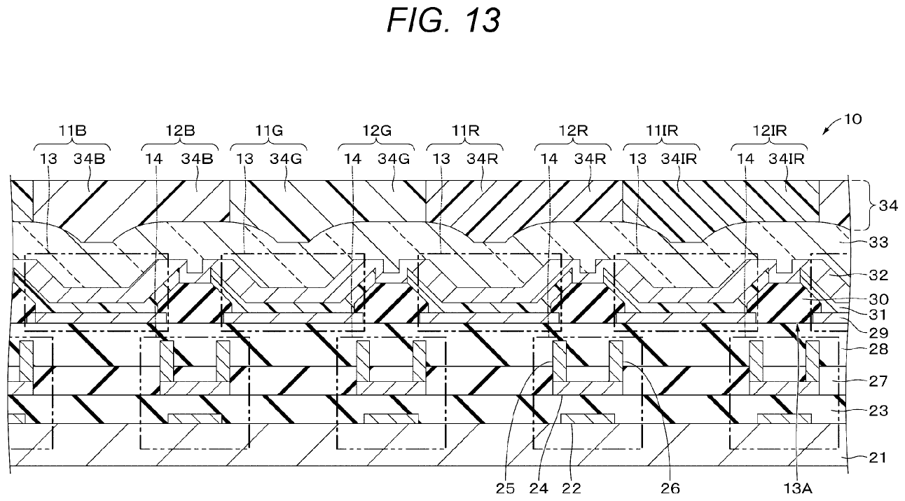

In the first embodiment described above, a description has been given to an example in which the organic EL layer 31 is provided continuously over all the light emitting elements 13 in the light emitting and receiving region, and is a layer (see FIG. 2) common to all the light emitting units 11 in the light emitting and receiving region. However, as illustrated in FIG. 13, the organic EL layer 31 may be divided between adjacent light emitting elements 13.

[Modification 6]

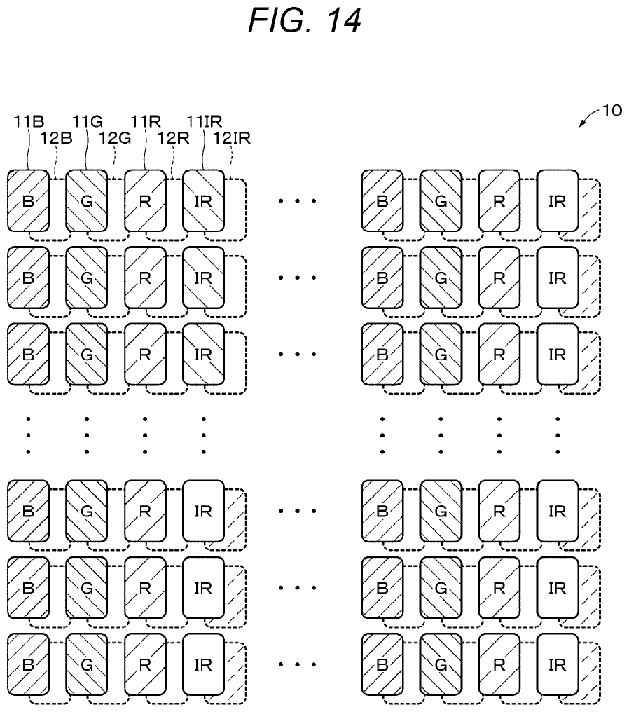

In the first embodiment, the control unit 51 may sequentially change lighting positions of the plurality of light emitting units 11IR to perform line-of-sight detection. Specifically, the control unit 51 may perform line-of-sight detection by controlling driving of the plurality of light emitting units 11 and the plurality of light receiving units 12 as follows. As illustrated in FIG. 14, when an image is being displayed by the plurality of light emitting units 11B, 11G, and 11R, the control unit 51 turns ON (performs the light emission driving on) some of the light emitting units 11IR among the plurality of light emitting units 11IR arranged in the light emitting and receiving region, and causes infrared light (illumination) invisible to the user to exit. Note that, in FIG. 14, hatched light emitting units 11 indicate the light emitting units 11 that are turned ON (subjected to the light emission driving), and unhatched light emitting units 11 indicate the light emitting units 11 that are not turned ON (not subjected to the light emission driving). The some of the above-described light emitting units 11R that are turned ON are, for example, a prescribed number of light emitting units 11IR aligned in the vertical direction or the horizontal direction.

The control unit 51 captures an image of a line-of-sight with the plurality of light receiving units 12IR arranged outside the vicinity of the some of the light emitting units 11IR described above that are turned ON (for example, other than the closest to the some of the light emitting units described above that are turned ON). Note that, in FIG. 14, hatched light receiving units 12IR indicate the light receiving units 12IR that are subjected to the light reception driving, and non-hatched light receiving units 12IR indicate the light receiving units 12IR that are not subjected to the light reception driving. The control unit 51 controls driving of the plurality of light emitting units 11IR and the plurality of light receiving units 12IR such that some of the light emitting units 11IR to be turned ON are sequentially changed and reflected light is received by a plurality of light receiving units 12IR arranged outside a periphery of the some of the light emitting units 11IR to be turned ON.

The light receiving units 12B, 12G, and 12IR may be subjected to the light reception driving. In this case, the degradation amount calculation unit 52A may calculate a degradation amount of the light emitting element 13 included in each of the light receiving units 12B, 12G, and 12IR on the basis of light reception signals output from the light receiving units 12B, 12G, and 12IR, and output a calculation result to the luminance correction unit 53.

The control unit 51 may drive the plurality of light receiving units 12IR arranged in the vicinity of the some of the light emitting units 11IR described above that are turned ON. In this case, the degradation amount calculation unit 52A may calculate the degradation amount of the light emitting element 13 included in the light emitting unit 11IR on the basis of light reception signals output from the plurality of light receiving units 12IR, and output a calculation result to the luminance correction unit 53.

In the light emitting and receiving device 10 according to Modification 6, as described above, lighting positions of the plurality of light emitting units 11IR are sequentially changed, so that it is possible to suppress degradation of detection accuracy of a line-of-sight due to a bright spot of illumination. Here, the light emitting and receiving device 10 according to the first embodiment has been described as an example, but the configuration described above can also be applied to the light emitting and receiving device 110 according to the second embodiment.

[Modification 7]

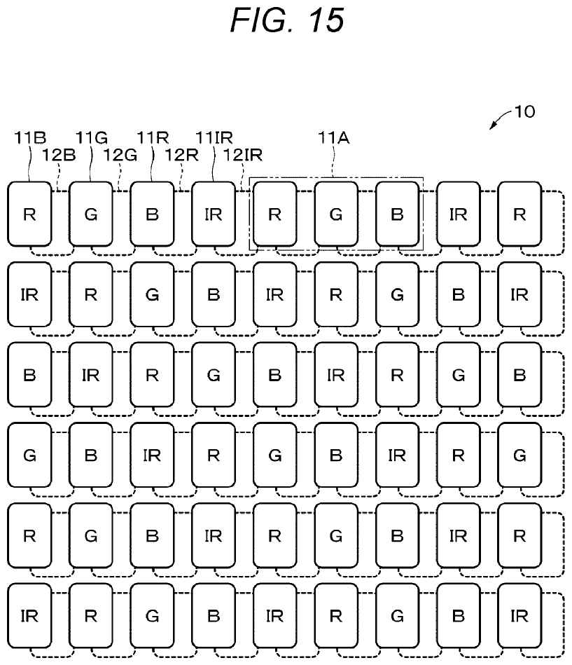

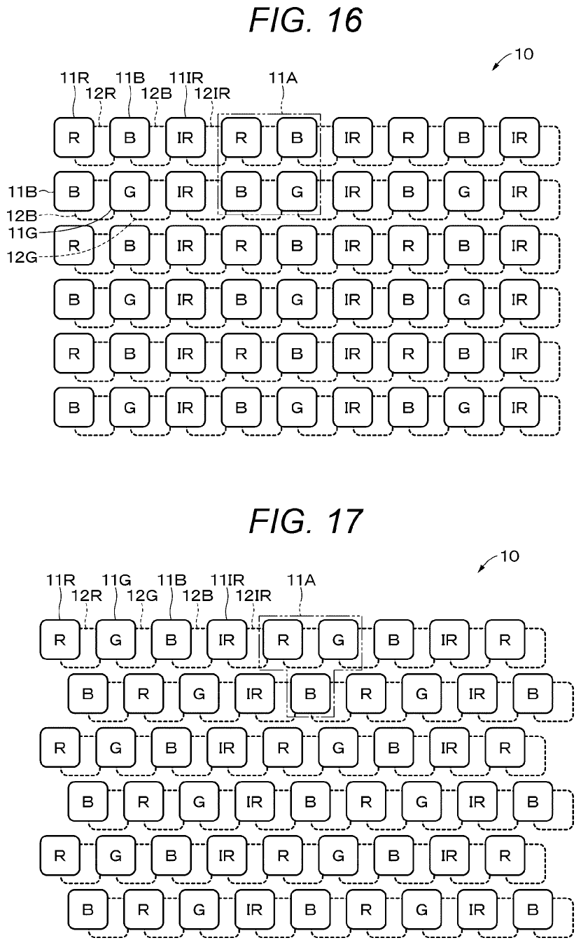

In the first and second embodiments described above, an example has been described in which the plurality of light emitting units 11B, 11G, and 11R constituting the plurality of subpixels is arranged in a stripe pattern (see FIG. 1). However, the plurality of light emitting units 11B, 11G, and 11R may be arranged in a mosaic form as illustrated in FIG. 15, may be arranged in a square lattice form as illustrated in FIG. 16, or may be arranged in a delta form as illustrated in FIG. 17.

[Modification 8]

In the first and second embodiments described above, an example has been described in which heights of the plurality of light emitting elements 13 and 113 from the first surface of the drive substrate 21 are higher than heights of the plurality of light receiving elements 14 from the first surface of the drive substrate 21. However, the heights of the plurality of light receiving elements 14 from the first surface of the drive substrate 21 may be higher than the heights of the plurality of light emitting elements 13 and 113 from the first surface of the drive substrate 21.

[Modification 9]

In the first and second embodiments described above, an example has been described in which the arrangement pattern of the plurality of light receiving elements 14 is the same as the arrangement pattern of the plurality of light emitting elements 13 and 113. However, the arrangement pattern of the plurality of light receiving elements 14 may be different from the arrangement pattern of the plurality of light emitting elements 13.

[Modification 10]

The light emitting and receiving device 110 according to the second embodiment described above may further include a protective layer and a color filter on the first surfaces of the plurality of second electrodes 132 and the insulating layer 130. The color filter includes a plurality of blue colored layers, a plurality of green colored layers, a plurality of red colored layers, and a plurality of infrared light transmitting layers. Functions of the colored layer of each color and the infrared light transmitting layer are similar to the functions of the colored layers 34B, 34G, and 34R of individual colors and the infrared light transmitting layer 34IR in the first embodiment. The colored layer of each color is individually provided to face the light receiving element 14. As a result, a full-color image can be captured. The infrared light transmitting layer is provided to face the light receiving element 14. As a result, infrared light can be received by the light receiving element 14. The colored layer of each color may be provided to face both the light emitting element 13 and the light receiving element 14 located closest to this light emitting element 13. The infrared light transmitting layer may be provided to face both the light receiving element 14 and the light receiving element 14 located closest to this light emitting element 13.

[Modification 11]

In the first embodiment described above, an example has been described in which the light emitting and receiving device 10 includes the four types of light emitting units 11B, 11G, 11R, and 11IR having individually different peak emission wavelengths. However, one type of light emitting units having the same peak emission wavelength may be provided, or two or more types of light emitting units having individually different peak emission wavelengths may be provided. Specifically, for example, the light emitting and receiving device 10 may include any one type of light emitting unit among the light emitting units 11B, 11G, 11R, and 11IR, or may include two or more types of light emitting units among the light emitting units 11B, 11G, 11R, and 11IR. Here, the light emitting and receiving device 10 according to the first embodiment has been described as an example, but the configuration described above can also be applied to the light emitting and receiving device 110 according to the second embodiment.

[Modification 12]

In the first embodiment described above, an example has been described in which a pixel for image display includes the light emitting units 11 of three colors, that is, the light emitting unit 11B that causes blue light to exit, the light emitting unit 11G that causes green light to exit, and the light emitting unit 11R that causes red light to exit. However, the combination of colors of the light emitting units constituting the pixel for image display is not limited thereto. For example, in the light emitting and receiving device 10, the pixel for image display may include light emitting units of three colors, that is, a light emitting unit that causes cyan light to exit, a light emitting unit that causes magenta light to exit, and a light emitting unit that causes yellow light to exit. Here, the light emitting and receiving device 10 according to the first embodiment has been described as an example, but the configuration described above can also be applied to the light emitting and receiving device 110 according to the second embodiment.

[Modification 13]

In the first embodiment described above, an example has been described in which all the plurality of light receiving elements 14 included in the light emitting and receiving device 10 has the same configuration, and is capable of detecting at least white light and infrared light, that is, capable of detecting all of blue light, green light, red light, and infrared light caused to exit respectively from the light emitting units 11B, 11G, 11R, and 11IR. However, the configuration of the plurality of light receiving elements 14 included in the light emitting and receiving device 10 is not limited to this example.

For example, the light receiving element 14 included in one of the light receiving units 12B closest to the light emitting unit 11B may have a configuration capable of detecting only blue light caused to exit from the light emitting unit 11B, the light receiving element 14 included in one of the light receiving units 12G closest to the light emitting unit 11G may have a configuration capable of detecting only green light caused to exit from the light emitting unit 11G, the light receiving element 14 included in one of the light receiving units 12R closest to the light emitting unit 11R may have a configuration capable of detecting only red light caused to exit from the light emitting unit 11R, and the light receiving element 14 included in one of the light receiving units 12IR closest to the light emitting unit 11IR may have a configuration capable of detecting only infrared light caused to exit from the light emitting unit 11IR. In this case, the colored layers 34B, 34G, and 34R and the infrared light transmitting layer 34IR may not cover the light receiving units included in the light receiving units 12B, 12G, 12R, and 12IR. Here, the light emitting and receiving device 10 according to the first embodiment has been described as an example, but the configuration described above can also be applied to the light emitting and receiving device 110 according to the second embodiment.

[Modification 14]

In the light emitting and receiving device 10 according to the first embodiment described above, at least one type of layer selected from a group including the interlayer insulating layer 27, the planarization layer 28, the insulating layer 30, and the protective layer 33 may have spectral characteristics of transmitting light in a specific wavelength region and shielding or reducing light other than the specific wavelength region described above. Hereinafter, the layer given with the spectral characteristics described above is referred to as a spectral layer. The light in the specific wavelength region described above is, for example, blue light, blue light, red light, or infrared light. The spectral characteristics of the spectral layer may be different depending on a position in the in-plane direction of the light emitting and receiving surface.

For example, the spectral layer may have the following spectral characteristics. In the spectral layer, spectral characteristics similar to those of the blue colored layer 34B may be imparted to portions corresponding to the light emitting unit 11B and the light receiving unit 12B. In the spectral layer, spectral characteristics similar to those of the green colored layer 34G may be imparted to portions corresponding to the light emitting unit 11G and the light receiving unit 12G. In the spectral layer, spectral characteristics similar to those of the red colored layer 34R may be imparted to portions corresponding to the light emitting unit 11R and the light receiving unit 12R. In the spectral layer, spectral characteristics similar to those of the infrared light transmitting layer 34IR may be imparted to portions corresponding to the light emitting unit 11IR and the light receiving unit 12IR. In this case, the color filter 34 may or may not be provided. In the example described above, an example has been described in which predetermined spectral characteristics are imparted to portions of the spectral layer corresponding to the light emitting unit 11 and the light receiving unit 12. However, in the spectral layer, predetermined spectral characteristics may be imparted to a portion corresponding to the light emitting unit 11 or the light receiving unit 12. Here, the light emitting and receiving device 10 according to the first embodiment has been described as an example, but the configuration described above can also be applied to the light emitting and receiving device 110 according to the second embodiment.

[Modification 15]

In the first embodiment described above, an example has been described in which a light extraction method of the light emitting and receiving device 10 is a top emission method, but the light extraction method may be a bottom emission method. Furthermore, a light extraction direction may be different for each of the light emitting units 11B, 11G, 11R, and 11IR. For example, the light extraction direction of the light emitting units 11B, 11G, and 11R may be different from the light extraction direction of the light emitting unit 11IR. Here, the light emitting and receiving device 10 according to the first embodiment has been described as an example, but the configuration described above can also be applied to the light emitting and receiving device 110 according to the second embodiment.

[Modification 16]

In the first and second embodiments described above, a method of receiving external light from the top side of the light emitting and receiving devices 10 and 110 has been described as an example, but a method of receiving external light from the bottom side may be used. Furthermore, a direction of receiving external light may be different for each of the light receiving units 12B, 12G, 12R, and 12IR. For example, the direction of receiving external light of the light receiving units 12B, 12G, and 12R may be different from the direction of receiving external light of the light emitting unit 11IR. Here, the light emitting and receiving device 10 according to the first embodiment has been described as an example, but the configuration described above can also be applied to the light emitting and receiving device 110 according to the second embodiment.

[Modification 17]

In the first and second embodiments described above, a system in which light extraction and light reception are performed from the top side has been described as an example, but directions of light extraction and light reception may be different. That is, while light is extracted on one side of the top side or the bottom side, light may be received on another side of the top side or the bottom side.

[Modification 18]

In the first embodiment described above, a method of combining the light emitting element 13 and the colored layers 34B, 34G, and 34R has been described as a coloring method, but the coloring method is not limited thereto. For example, a method of extracting three-color light (red light, green light, and blue light) by a resonator structure instead of the colored layers 34B, 34G, and 34R may be used, or a method of enhancing color purity by using the colored layers 34B, 34G, and 34R and the resonator structure in combination may be used. Furthermore, a method of extracting infrared light by a resonator structure instead of the infrared light transmitting layer 341R may be used, or a method of enhancing purity of infrared light by using the infrared light transmitting layer 341R and the resonator structure in combination may be used.

[Modification 19]

The light emitting and receiving device 10 according to the first embodiment described above may further include a filling resin layer and a counter substrate in this order on the first surface of the color filter 34. The filling resin layer has a function as an adhesive layer for bonding the color filter 34 and the counter substrate. The filling resin layer includes, for example, at least one selected from a group including a thermosetting resin, an ultraviolet curable resin, and the like. The counter substrate is provided to face the drive substrate 21. The counter substrate seals the plurality of light emitting units 11, the plurality of light receiving units 12, and the like. The counter substrate contains a material such as glass that is transparent to each color light and infrared light caused to exit from the color filter 34. The light emitting and receiving device 110 according to the second embodiment described above may further include a filling resin layer and a counter substrate on the first surfaces of the plurality of second electrodes 132 and the insulating layer 130 in this order.

[Modification 20]

In the first embodiment described above, an example in which the color filter 34 is an on-chip color filter has been described, but the arrangement of the color filter 34 is not limited thereto. For example, the color filter 34 may be provided on the second surface of the counter substrate.

### 4. Application Example

(Electronic Device)

The light emitting and receiving devices 10 and 110 (hereinafter, referred to as “the light emitting and receiving device 10 and the like”) according to the first and second embodiments and the modifications thereof described above can be included in various electronic devices. The light emitting and receiving device 10 and the like are particularly suitable for those required to have high resolution and enlarged and used near the eyes, such as a display of a head-mounted type.

### Specific Example 1

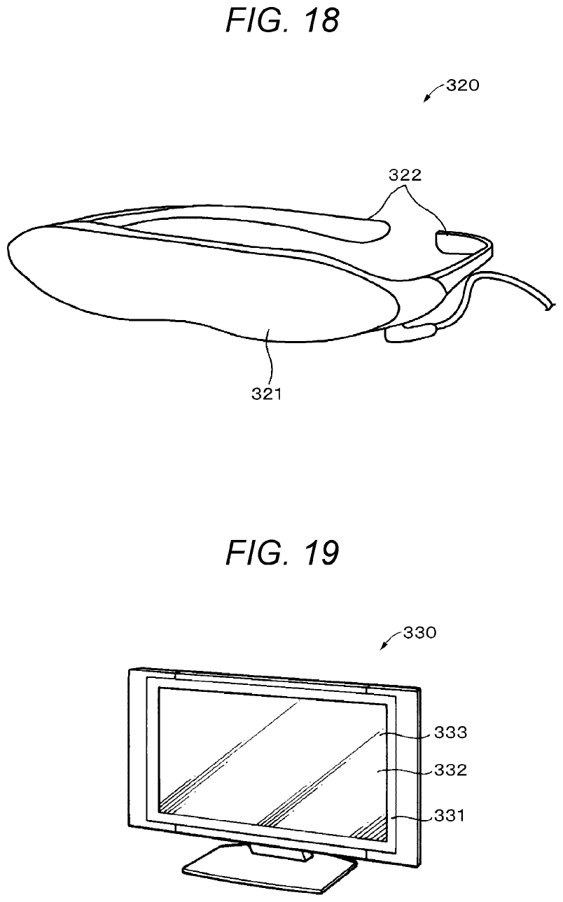

FIG. 18 illustrates an example of an external appearance of a head mounted display 320. The head mounted display 320 includes, for example, ear hooking portions 322 to be worn on the head of the user on both sides of a glass-shaped display unit 321. As the display unit 321, any one of the light emitting and receiving device 10 and the like can be used.

### Specific Example 2

FIG. 19 illustrates an example of an external appearance of a display device 330. The display device 330 includes, for example, a video display screen unit 331 including a front panel 332 and a filter glass 333, and the video display screen unit 331 includes any of the light emitting and receiving device 10 and the like.

Although the first and second embodiments of the present disclosure and modifications thereof have been specifically described above, the present disclosure is not limited to the above-described first and second embodiments and modifications thereof, and various modifications based on the technical idea of the present disclosure are possible.

For example, the configurations, methods, steps, shapes, materials, numerical values, and the like mentioned in the above-described first and second embodiments and modifications thereof are merely examples, and configurations, methods, steps, shapes, materials, numerical values, and the like different from these may be used as necessary.

The configurations, methods, steps, shapes, materials, numerical values, and the like of the above-described first and second embodiments and modifications thereof can be combined with each other without departing from the gist of the present disclosure.

The materials exemplified in the above-described first and second embodiments and modifications thereof can be used alone or in combination of two or more unless otherwise specified.

Furthermore, the present disclosure can also adopt the following configurations.

(1)

A light emitting and receiving device including:
a plurality of light emitting elements; and
a plurality of light receiving elements, in which
the plurality of light emitting elements is two-dimensionally arranged separately, and
the plurality of light receiving elements is two-dimensionally arranged at a height different from a height of the plurality of light emitting elements, and each of the light receiving elements faces an inter-element separation portion between the light emitting elements that are adjacent.

(2)

The light emitting and receiving device according to (1), further including:
a filter, in which
the filter includes a plurality of colored layers and a plurality of infrared light transmitting layers,
the plurality of colored layers individually faces some of the plurality of light emitting elements,
the plurality of infrared light transmitting layers individually faces a rest of the plurality of light emitting elements, and
the plurality of light emitting elements is configured to be able to cause at least white light and infrared light to exit.

(3)

The light emitting and receiving device according to (2), in which the plurality of colored layers includes a plurality of colored layers of a first color, a plurality of colored layers of a second color, and a plurality of colored layers of a third color.

(4)

The light emitting and receiving device according to (2) or (3), in which
each of the colored layers covers each of the light receiving elements located in a vicinity of each of the light emitting elements facing the each of the colored layers, and
each of the infrared light transmitting layers covers each of the light receiving elements located in a vicinity of each of the light emitting elements facing the each of the infrared light transmitting layers.

(5)

The light emitting and receiving device according to (4), in which
each of the colored layers and each of the light emitting elements facing the each of the colored layers constitute a subpixel for image display,
each of the colored layers and each of the light receiving elements covered with the each of the colored layers constitute a subpixel for image capturing,
each of the infrared light transmitting layers and each of the light emitting elements facing the each of the infrared light transmitting layers constitute a light emitting unit that emits infrared light, and
each of the infrared light transmitting layers and each of the light receiving elements covered with the each of the infrared light transmitting layers constitute a light receiving unit that receives infrared light.

(6)

The light emitting and receiving device according to any one of (2) to (5), further including:
a control unit configured to control driving of the plurality of light emitting elements and the plurality of light receiving elements, in which
the control unit sequentially changes lighting positions of the plurality of light emitting elements individually facing the plurality of infrared light transmitting layers.

(7)

The light emitting and receiving device according to any one of (2) to (6), in which
the filter has a plurality of openings, and
each of the plurality of openings faces each of the light receiving elements.

(8)

The light emitting and receiving device according to any one of (2) to (6), in which
the filter further includes a plurality of spectral layers, and
each of the plurality of spectral layers faces each of the light receiving elements.

(9)

The light emitting and receiving device according to any one of (2) to (8), in which each of the light emitting elements includes a first electrode, an organic layer including a light emitting layer, and a second electrode.

(10)

The light emitting and receiving device according to (1), in which the plurality of light emitting elements includes a plurality of visible light emitting elements that causes visible light to exit and a plurality of infrared light emitting elements that causes infrared light to exit.

(11)

The light emitting and receiving device according to (10), in which the plurality of visible light emitting elements includes a plurality of first visible light emitting elements that causes light of a first color to exit, a plurality of second visible light emitting elements that causes light of a second color to exit, and a plurality of third visible light emitting elements that causes light of a third color to exit.

(12)

The light emitting and receiving device according to any one of (1) to (11), in which each of the light receiving elements is arranged to be biased to one side of the light emitting elements that are adjacent.

(13)

The light emitting and receiving device according to any one of (1) to (12), in which
in a case of assuming a plane that divides each of the light receiving elements into two portions, the two portions being a portion on one element side of the light emitting elements that are adjacent and a portion on another element side of the light emitting elements that are adjacent,
each of the light receiving elements has asymmetry with respect to the plane.

(14)

The light emitting and receiving device according to any one of (1) to (13), further including:
an insulating layer provided in the inter-element separation portion, in which
the insulating layer is configured to transmit light in a prescribed wavelength region.

(15)

The light emitting and receiving device according to any one of (1) to (14), in which each of the light receiving elements is configured to be able to receive external light and exit light from each of the light emitting elements located in a vicinity of the each of the light receiving elements.

(16)

An electronic device including the light emitting and receiving device according to any one of (1) to (15).

### REFERENCE SIGNS LIST

10, 110 Display device
11A Pixel
11B, 11G, 11R, 11IR, 111B, 111G, 111R, 111IR Light emitting unit
12, 12B, 12G, 12R, 12IR, 112 Light receiving unit
13, 113 Light emitting element
14 Light receiving element
21 Drive substrate
22 Gate electrode
23 Gate insulating layer
24 Semiconductor layer
25 Source electrode
26 Drain electrode
27 Interlayer insulating layer
28 Planarization layer
29 First electrode
30 Insulating layer
30A Opening
31, 131B, 131G, 131R, 131IR Organic electroluminescence layer
32, 132 Second electrode
33 Protective layer
34 Color filter
34A Opening
34B, 34G, 34R Colored layer
34IR Infrared light transmitting layer
35 Spectral layer
40A Display region
40B Peripheral region
41 Signal line drive circuit
41A Signal line
42 Scanning line drive circuit
42A Scanning line
43 Light reception signal reading circuit
43A Signal line
44 Light reception drive circuit
44A Scanning line
44B Power supply line
44C Gate line
50 Light emission and reception processing device
51 Control unit
52 Calculation unit
52A Degradation amount calculation unit
52B External light amount calculation unit
53 Luminance correction unit
320 Head mounted display (electronic device)
330 Display device (electronic device)

1. A light emitting and receiving device comprising:
a plurality of light emitting elements; and
a plurality of light receiving elements, wherein
the plurality of light emitting elements is two-dimensionally arranged separately, and
the plurality of light receiving elements is two-dimensionally arranged at a height different from a height of the plurality of light emitting elements, and each of the light receiving elements faces an inter-element separation portion between the light emitting elements that are adjacent.

2. The light emitting and receiving device according to claim 1, further comprising:
a filter, wherein
the filter includes a plurality of colored layers and a plurality of infrared light transmitting layers,
the plurality of colored layers individually faces some of the plurality of light emitting elements,
the plurality of infrared light transmitting layers individually faces a rest of the plurality of light emitting elements, and
the plurality of light emitting elements is configured to be able to cause at least white light and infrared light to exit.

3. The light emitting and receiving device according to claim 2, wherein the plurality of colored layers includes a plurality of colored layers of a first color, a plurality of colored layers of a second color, and a plurality of colored layers of a third color.

4. The light emitting and receiving device according to claim 2, wherein
each of the colored layers covers each of the light receiving elements located in a vicinity of each of the light emitting elements facing the each of the colored layers, and
each of the infrared light transmitting layers covers each of the light receiving elements located in a vicinity of each of the light emitting elements facing the each of the infrared light transmitting layers.

5. The light emitting and receiving device according to claim 4, wherein
each of the colored layers and each of the light emitting elements facing the each of the colored layers constitute a subpixel for image display,
each of the colored layers and each of the light receiving elements covered with the each of the colored layers constitute a subpixel for image capturing,
each of the infrared light transmitting layers and each of the light emitting elements facing the each of the infrared light transmitting layers constitute a light emitting unit that emits infrared light, and
each of the infrared light transmitting layers and each of the light receiving elements covered with the each of the infrared light transmitting layers constitute a light receiving unit that receives infrared light.

6. The light emitting and receiving device according to claim 2, further comprising:
a control unit configured to control driving of the plurality of light emitting elements and the plurality of light receiving elements, wherein
the control unit sequentially changes lighting positions of the plurality of light emitting elements individually facing the plurality of infrared light transmitting layers.

7. The light emitting and receiving device according to claim 2, wherein
the filter has a plurality of openings, and
each of the plurality of openings faces each of the light receiving elements.

8. The light emitting and receiving device according to claim 2, wherein
the filter further includes a plurality of spectral layers, and
each of the plurality of spectral layers faces each of the light receiving elements.

9. The light emitting and receiving device according to claim 1, wherein each of the light emitting elements includes a first electrode, an organic layer including a light emitting layer, and a second electrode.

10. The light emitting and receiving device according to claim 1, wherein the plurality of light emitting elements includes a plurality of visible light emitting elements that causes visible light to exit and a plurality of infrared light emitting elements that causes infrared light to exit.

11. The light emitting and receiving device according to claim 10, wherein the plurality of visible light emitting elements includes a plurality of first visible light emitting elements that causes light of a first color to exit, a plurality of second visible light emitting elements that causes light of a second color to exit, and a plurality of third visible light emitting elements that causes light of a third color to exit.

12. The light emitting and receiving device according to claim 1, wherein each of the light receiving elements is arranged to be biased to one side of the light emitting elements that are adjacent.

13. The light emitting and receiving device according to claim 1, wherein
in a case of assuming a plane that divides each of the light receiving elements into two portions, the two portions being a portion on one element side of the light emitting elements that are adjacent and a portion on another element side of the light emitting elements that are adjacent,
each of the light receiving elements has asymmetry with respect to the plane.

14. The light emitting and receiving device according to claim 1, further comprising:
an insulating layer provided in the inter-element separation portion, wherein
the insulating layer is configured to transmit light in a prescribed wavelength region.

15. The light emitting and receiving device according to claim 1, wherein each of the light receiving elements is configured to be able to receive external light and exit light from each of the light emitting elements located in a vicinity of the each of the light receiving elements.

16. An electronic device comprising the light emitting and receiving device according to claim 1.
